(19) United States
(12) Patent Application Publication
(10) Pub. No.: US 2016/0222039 A1
(43) Pub. Date: Aug. 4, 2016

(54) SPINTRONIC MATERIALS AND SPINTRONIC DEVICES INCLUDING THE SPINTRONIC MATERIALS

(71) Applicant: NANYANG TECHNOLOGICAL UNIVERSITY, Singapore (SG)

(72) Inventors: Tze Chien SUM, Singapore (SG); David GIOVANNI, Singapore (SG); Nripan MATHEWS, Singapore (SG); Subodh Gautam MHAISALKAR, Singapore (SG)

(73) Assignee: NANYANG TECHNOLOGICAL UNIVERSITY, Singapore (SG)

(21) Appl. No.: 15/009,916

(22) Filed: Jan. 29, 2016

(30) Foreign Application Priority Data
Jan. 29, 2015 (SG) 10201500726T

(51) Int. Cl. C07F 7/24; H01L 43/10

(52) U.S. Cl. CPC C07F 7/24; H01L 43/10

(57) ABSTRACT

The invention relates to spintronic materials, and in particular, to spintronic materials comprised of halide perovskite compounds. In various embodiments, the spintronic material comprises a solution processed halide perovskite compound. A method for forming the solution processed halide perovskite compound is also disclosed.

### CROSS-REFERENCE TO RELATED APPLICATION

This application claims the benefit of priority of Singapore Patent Application No. 10201500726T, filed Jan. 29, 2015, the contents of which being hereby incorporated by reference in its entirety for all purposes.

### TECHNICAL FIELD

The invention relates to spintronic materials, and in particular, to spintronic materials comprised of halide perovskite compounds.

### BACKGROUND

Spintronic (portmanteau of “spin” and “electronics”) is an emerging branch or technology which exploits the intrinsic spin of an electron and its associated magnetic moment in addition to its charge degree of freedom. Spintronic has a lot to offer, in particular, enhancing the efficiency of existing electronic devices and empowering them with new functionalities. Examples of demonstrated spintronic applications include the read head of Hard Disk Drive (HDD) and Magnetoresistive Random Access Memory (MRAM). Besides these examples, there are many other possible applications such as spin-transistors, spin filters, spin valves, ultrafast spin switches, spin-polarized light emitting diodes (LEDs), quantum computing, and non-volatile storing devices, etc.

Preferably, an ideal spintronic material should possess the following desirable properties: long carrier-diffusion lengths and relaxation times for transport, suitable band structure for spin injection, spin polarized charge carrier behavior and fast spin relaxation for spin switches, etc. Another important aspect is that whether the spin properties of the material are controllable and switchable, e.g. through magnetoelectric effect, that allows manipulation of the magnetic (electric) properties with external electric (magnetic) field.

Known spintronic materials include metal-based ferromagnetic such as ferrite (Fe₂O₃) for read head of HDD and a combination of some metal elements in layered structure such as cobalt (Co), iron (Fe), chromium (Cr), and palladium (Pd) for MRAM. Most common materials for semiconductor spin-based research are gallium arsenide (GaAs) whose band structure is suitable for optical spin injection and the ubiquitous silicon (Si) platform where most conductor devices are built upon. As the material quality (especially purity and crystallinity) plays an important role in the device performance, it is important to note that stringent conditions are needed to prepare the high quality, crystalline materials, which necessitate costly high temperature growth and processing. For example, GaAs require expensive elevated temperature and high vacuum growth techniques such as chemical vapor deposition (CVD) and molecular beam epitaxy (MBE).

Therefore, there remains an unmet need to develop low temperature, solution processable high crystallinity spintronic materials which possess the above-mentioned desirable properties for spintronic applications. This would not only reduce the production costs but also possibly open up spin-based research to a much wider range of spintronic devices and designs.

### SUMMARY

Present disclosure describes the application of low-temperature solution-processed halide perovskite materials as spintronic media that could be driven by both photons and electrons.

In one aspect, there is disclosed a method for forming halide perovskite compound, the method comprising:
dissolving RX and MX₂ in a solvent to form a precursor solution, wherein R comprises a mono-positive organic group or inorganic cation, M comprises a divalent metal and X comprises I, Cl, Br, F, or a mixture thereof;
depositing the precursor solution onto a substrate; and
heating the deposited precursor solution to form a film of the halide perovskite compound.

In another aspect, a spintronic device comprising a spintronic material, wherein the spintronic material comprises a halide perovskite compound is disclosed. In various embodiments, the halide perovskite compound comprises the halide perovskite compound formed by the earlier aspect.

The relatively strong spin-orbit coupling (SOC) in the perovskite materials formed by present method heavily modified its band structure to allow perfect angular momentum J (correspond to spin) polarization through optical injection. Moreover, these materials strongly interact with light, as evident from their giant photoinduced Faraday Effect, reaching 10°/μm for the case of CH₃NH₃PbI₃ and large Rabi splitting of 55 meV in room temperature for the case of (C₅H₄FC₂H₄NH₃)₂PbI₄ as demonstrated by the inventors. Coupled with other excellent properties such as ultralow trap density, ultralow gain thresholds, high optical stability and durability make these materials to be an excellent candidate for applications spin-optoelectronics (e.g. ultrafast spin filters or spin-polarized light emitting devices).

Another unique feature of these materials is their long range balanced electrons and holes diffusion lengths that makes it possible to achieve efficient electrically-driven spin-polarized devices in this class of materials. A solution processable material has much greater versatility than traditional semiconductor spin media for integration with existing silicon based technologies. It can be applied to a much wider range of devices and substrates by simply spin-coating, dip-coating or drop-casting. Another advantage of this class of materials is its tunability of the properties such as the SOC, band-gap, etc., by facile substitution of the metal element and organic component to suit the needs for particular applications.

### BRIEF DESCRIPTION OF THE DRAWINGS

In the drawings, like reference characters generally refer to the same parts throughout the different views. The drawings are not necessarily drawn to scale, emphasis instead generally being placed upon illustrating the principles of various embodiments. In the following description, various embodiments of the invention are described with reference to the following drawings.

FIG. 1A shows optical selection rule for near band-edge of lead halide perovskite. The state notation is written as |J,m_{J} [symbol] where J=½ is electron's total angular momentum quantum number and m_{J}=±½ is its projection in the z-axis. Absorption of σ^{±} pump will raise the angular momentum by ±1 (Δm_{J}=±1). FIG. 1B shows normalized degenerate circular pump-probe data with given pump and probe polarization for CH₃NH₃PbI₃ at band edge. FIG. 1C shows normalized degenerate circular pump-probe data with given pump and probe polarization for (C₆H₅C₂H₄NH₃)₂PbI₄ at exciton peak. Each probe polarization will trace population of different J-states. The two signals σ⁺ and σ⁻ probe flips when pump polarization is flipped from σ⁺ to σ⁻ and become symmetric when the pump polarization is σ⁰ (linear), which is the signature of selective J-states excitation.

FIG. 2A-B show time-resolved Faraday rotation (TRFR) study on CH₃NH₃PbI₃ 70 nm-thick film at fluence 19 μJ/cm², where FIG. 2A shows typical signal of pump-induced Faraday rotation which is proportional to sample magnetization at 200 K. Switching pump polarization between σ⁺ (circle) and σ⁻ (square) will flip the signal, while no rotation is observed for σ⁰ (linear, triangle) polarization, and FIG. 2B shows maximum rotation (peak) as function of temperature.

FIG. 3A and FIG. 3B show, respectively, spectral-resolved and time-resolved transient absorption study of OSE at room temperature with various pump (2.16 eV, 0.416 mJ/cm²) and probe helicity in (C₆H₅C₂H₄NH₃)₂PbI₄ at 0.4 ps delay. The splitting in exciton spin-states depending on the pump helicity is reflected by the change of σ⁺ (dashed line) and σ⁻ (solid line) absorption of the probe.

FIG. 4A shows crystal structure of 2D halide perovskite (C₆H₅C₂H₄NH₃)₂PbI₄ which forms a natural multiple quantum well with the inorganic and organic layer as the well and barrier, respectively. FIG. 4B shows tunability of the strength of light-matter coupling in 2D lead halide perovskite quantized by the Rabi splitting per square root of pump fluence, by changing the dielectric contrast between the well and the barrier, i.e. changing the organic and halide component. PEPB stands for phenyl-ethyl-ammonium lead bromide ((C₆H₅C₂H₄NH₃)₂PbBr₄), PEPI stands for phenyl-ethyl-ammonium lead iodide ((C₆H₅C₂H₄NH₃)₂PbI₄) and FPEPI stands for fluorinated-PEPI ((C₆H₅C₂H₄NH₃)₂PbI₄).

FIG. 5 shows spin-selective OSE for spin-switch or spin-filter. The concept of an optical spin-switch or spin-filter based on the spin-selective OSE in PEPI is illustrated. The device architecture is based on an optically-gated field-effect transistor with the 2D halide perovskite as the semiconducting channel. A microcavity is added to enhance the energy level splitting (and Rabi-splitting). Without illumination, both the spin gate (up and down) are opened, yielding an unpolarised current. With the illumination of σ⁺ (σ⁻), the spin-up (down) energy level is selectively lifted up due to OSE, leaving the spin-down (up) energy level unchanged. This allows only spin-down (up) polarized current to pass, hence achieving spin switching/filtering.

FIG. 6A shows energy bands of CH₃NH₃PbI₃ at R-point (point group symmetry representation) with their respective levels from vacuum (experimental). Dashed box indicates the bands of interest. FIG. 6B shows model of near band-edge photoexcitation by σ⁺ photon and J-states dynamics of CH₃NH₃PbI₃. The state notation is written as |J,m_{J} [symbol] where J=½ is electron's total angular momentum quantum number and m_{J}=±½ its projection in the z-axis. Absorption of σ⁺ pump will raise the angular momentum by +(Δm_{J}=±1). FIG. 6C shows normalized circular pump-probe decay transients with 19 μJ/cm² σ⁺ pump and σ⁺ probe, σ⁻ probe and their total, at 293 K (top) and 77 K (bottom). The experimental data is globally fitted using Eq. (3) (σ⁺ probe and σ⁻ probe) and Eq. (4) (their total).

FIG. 7A-B shows experimental data with 19 μJ/cm² pump at 77 K, where FIG. 7A shows the difference between σ⁺ and σ⁻ signal (square) is plotted together with the deconvoluted contribution from electrons (circle) and holes (triangle). Δƒₑ (Δƒₕ) denotes the population difference between spin-up and spin-down electrons (holes). FIG. 7B shows the degree of polarization dynamics after 0.5 ps of holes for spin and J (triangle), electrons J (square) and electrons spin (circle, absolute value).

FIG. 8A-B show measured spin relaxation time of electrons (square) and holes (circle), where FIG. 8A shows temperature dependence fitted with τ α T^{b} where it is obtained b=−0.27±0.06 for electrons and b=−0.55±0.15 for holes and FIG. 8B shows fluence dependence (for electrons). Holes spin relaxation time at high fluence is shorter than the inventors' temporal resolution and hence cannot be measured.

FIG. 9A-B show TRFR study on CH₃NH₃PbI₃ at fluence 19 μJ/cm², where FIG. 9A shows typical signal of pump-induced Faraday rotation which is proportional to sample magnetization, fitted with a bi-exponential decay function (τ₁=0.9±0.1 ps and τ₂=4±1 ps). Switching pump polarization between σ⁺ and σ⁻ will flip the signal, while no rotation is observed for σ⁰ polarization, and FIG. 9B shows maximum rotation (peak) as function of temperature.

FIG. 10A show an AFM wide-area scan over 30×30 μm² area on the film around the scratch. White box indicates the area taken for the thickness averaging where it is obtained film thickness of 70±10 μm. Box with number 1 and 2 label indicates the area plotted in FIG. 10B of position 1 (solid line) and 2 (dashed line) respectively, where ˜20 nm-high and 20 μm-wide swelling on the film edge was observed. Further into the sample from the edge (plot of position 2), the film thickness becomes more constant about the average value reported here. This swelling is most likely due to mechanical pressure during scratching.

FIG. 11A shows circularly polarized or spin dependent pump-probe experimental setup. Circle with dot and double-ended arrow indicate s and p polarization, respectively. FIG. 11B shows spectroscopists' convention for circular polarization from the source point of view. Left (σ⁺) and right (σ⁻) circularly polarized photon carry angular momentum of + and − in the direction of their propagation. FIG. 11C shows normalized circular pump-probe data with given pump and probe polarization. Each probe polarization will trace population of different J-states. The two signals σ⁺ and σ⁻ probe (circle and square respectively) flips when pump polarization is flipped from σ⁺ to σ⁻ and become symmetric when the pump polarization is σ⁰, which is the signature of selective J-states excitation.

FIG. 12A shows an illustration of pump-induced Faraday rotation. FIG. 12B shows detection for Faraday rotation angle.

FIG. 13A-D shows optical Stark effect in phenyl-ethyl-ammonium lead iodide (PEPI). FIG. 13A shows structure of PEPI with alternating organic and inorganic layers, forming multiple natural type-I QW structure with the barrier (well) being the organic (inorganic) layer, respectively. FIG. 13B shows an illustration of OSE in a two-level system represented by the equilibrium states (solid line) and the pump-induced Floquet quasi-state (dashed line) and the corresponding (i) linear absorption and (ii) transient absorption spectra. FIG. 13C shows the energy separation Δ between the excitonic absorption peak E₀ of a 45 nm-thick spin-coated PEPI film and the excitation pump ω. FIG. 13D shows TA spectrum of PEPI following linearly polarized pump and probe at 0.4 ps probe delay. Inset: Ultrafast kinetics of OSE showing a fast process comparable to the pulse duration.

FIG. 14A-D shows spin-selective optical Stark effect (OSE). FIG. 14A shows optical selection rule for the lowest singlet exciton in PEPI. Both the electron and hole have total angular momentum quantum number J=½ and magnetic quantum number m_{J}=±½. FIG. 14B shows a schematic of the spin-selective OSE mechanism in PEPI, showing only the m_{J} in ket notation. The arrow illustrates the interaction between the σ⁺ and σ⁻ photon that forms the Floquet quasi-states. The hybridization of the equilibrium states with the Floquet quasi-states results in the shift in energy levels. The dashed (solid) lines represent the energy levels before (after) the repulsion. Repulsion only occurs between the equilibrium states and the Floquet states with the same m_{J}. FIG. 14C shows co- and counter-circularly polarized pump and probe TA spectra at 0.4 ps probe delay, and FIG. 14D shows the corresponding kinetics at the negative ΔA peak (2.37 eV).

FIG. 15A-C shows fluence dependence of the OSE. FIG. 15A shows pump fluence dependent TA spectra for co-circular (solid line) and counter-circular (dashed line) polarization pump-probe at 0.4 ps probe delay. FIG. 15B shows resultant spectra from the difference between the co-circular TA spectra and the counter-circular TA spectra at the same pump fluence at 0.4 ps probe delay. The vertical dashed line indicates the position of the exciton absorption peak. FIG. 15C shows estimated Stark shift as function of pump fluence (circle, left axis) and two photoexcited exciton population (square, right axis) and as a function of pump fluence. The Stark shift exhibits a linear relation, while the two-photon excitation process exhibits a quadratic relation with the pump fluence.

FIG. 16 shows correlation between the Rabi splitting and the oscillator strength or dielectric contrast. Measurement of Rabi splitting via OSE on various lead-based 2D perovskite systems. Here, PEPB is phenyl-ethyl-ammonium lead bromide, PEPI is phenyl-ethyl-ammonium lead iodide and FPEPI is fluorinated-phenyl-ethyl-ammonium lead iodide. There is a clear increasing relation between ÅΩ_{R}/\sqrt{I} (circle) with the dielectric contrast. Meanwhile, no clear correlation is observed between with the oscillator strength (square) and ÅΩ_{R}/\sqrt{I}.

FIG. 17 shows transient absorption spectroscopy setup. The schematic of currently used femtosecond transient absorption spectroscopy setup used in this work (Example 2) for circularly pump and probe measurements. For the linearly pump and probe measurements, the SBC and the achromatic λ/4 waveplate were replaced with linear polarizers.

FIG. 18 shows the calculation of transient change due to positive x shift. When the function ƒ(x) is shifted in positive x-direction by Δx, the transient change at x due to the shift is given by Δƒ(x)=ƒ(x−Δx)−ƒ(x).

FIG. 19A-B shows quantum description of the Optical Stark Effect. FIG. 19A shows a schematic of the new eigenenergies of the photon-dressed states (solid line) in relation to the bare states (dashed line). The Optical Stark Effect (OSE) gives rise to the separation between the two eigenenergies in the dressed states as compared to the bare states. FIG. 19B shows dispersion relation for the two new photon-dressed eigenstates for the case of the exciton in a semiconductor.

FIG. 20 shows OSE with different pump detuning. Calculated spectral weight transfer (SWT) and estimated ΔE due to OSE for pump detuning Δ=0.23 eV (square, pump at 2.16 eV) and Δ=0.33 eV (circle, pump at 2.07 eV).

FIG. 21A-B shows pump properties in the energy and time domains. FIG. 21A shows pump spectra for 2.16 eV and 2.07 eV used in the present experiment with the FWHM values shown. FIG. 21B shows pump-probe cross-correlation obtained with 2.37 eV probe, for 2.16 eV and 2.07 eV with the FWHM values offset in the time axis for clarity.

FIG. 22A-D shows comparison of various halide perovskite with different dielectric contrast. FIG. 22A shows structural difference between organic component of PEPI and FPEPI. FIG. 22B and FIG. 22C show, respectively the stark shift and the Rabi splitting as function of pump fluence and FIG. 22D shows the absorption spectrum of PEPI (solid line), PEPB (dashed line) and FPEPI (dashed-dot line). The dielectric contrast between the barrier and the well is increasing with the following order: PEPB, PEPI and FPEPI.

FIG. 23 shows photoluminescence (PL) kinetics of PEPI. The PL kinetics by 3.1 eV pump with fluence of 10 μJ/cm². The kinetics is fitted with two lifetimes, which yields a short component of 210±10 ps (78%) and a long component of 610±40 ps (22%). The short component is attributed to spontaneous emission from the free exciton, while the long lifetime component originates from the bound exciton due to the spectral overlap of the free exciton and bound exciton peaks.

FIG. 24 shows kinetics of exciton in PEPI: the kinetics of 3.10 eV pump excitation, at 2.37 eV (square) and 2.44 eV (circle) probe, showing oscillatory signal with frequency of ˜1 THz.

### DESCRIPTION

The following detailed description refers to the accompanying drawings that show, by way of illustration, specific details and embodiments in which the invention may be practised. These embodiments are described in sufficient detail to enable those skilled in the art to practise the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Present disclosure describes the application of low temperature (i.e. 100° C. or lower) solution processed halide perovskite films or materials for spintronic devices which could be driven by both photons and electrons. The halide perovskite material may be represented by a general formula RMX₃, where R may be a mono-positive organic group or inorganic cation, M may be a divalent metal cation and X may be a halogen anion. Examples may include CH₃NH₃PbI₃, CH₃NH₃PbBr₃, CH₃NH₃PbBr₂I, CsPbI₃, CsSnI₃, NH₂(CH)NH₂PbI₃. The halide perovskite material may be alternatively represented by a general formula R₂MX₆, where R may be a mono-positive organic group or inorganic cation, M may be a tetravalent metal cation and X may be a halogen anion. Examples may include Cs₂SnI₆, (CH₃NH₃)₂SnI₆. The halide perovskite may also be represented by R₂MX₄, where R may be a mono-positive organic group or inorganic cation, M may be a divalent metal cation and X may be a halogen anion. Examples may include (C₄H₉NH₃)₂CuBr₄, (C₆H₅C₂H₄NH)₂SnBr₂I₂, (C₆H₅C₂H₄NH₃)₂PbI₄, (C₆H₄FC₂H₄NH₃)₂PbI₄. The halide perovskite may instead be represented by RMX₄, where R may be a bi-positive organic group or inorganic cation, M may be a divalent metal cation and X may be a halogen anion. Examples may include NH₃C₄H₈NH₃PbI₄ and NH₃C₄H₈NH₃SnBr₄. In various embodiments, the halide perovskites may include an organic ammonium cation, organic ammonium cation group. The organic group may be the organic ammonium cation or group. The organic ammonium group may be selected from a group consisting ammonium group, hydroxyl-ammonium group, hydrazinium group, azeditinium group, formamidinium group, imidazolium group, dimethylammonium group, guanidinium group, alkyl-ammonium group, arylalkyl-ammonium group and combination thereof. The organic ammonium cation may be selected from a group consisting of ammonium ion [NH4]⁺, hydroxyl-ammonium ion [H₃N—OH]⁺, hydrazinium ion [H₃N—NH₂]⁺, azeditinium ion [(CH₂)₃NH₂]⁺, formamidinium ion [NH₂(CH)NH₂]⁺, imidazolium ion [C₃N₂H₅]⁺, dimethylammonium ion [(CH₃)₂NH₂]⁺, guanidinium ion [C(NH₂)₃]⁺, alkyl-ammonium ion [CₙH₂ₙ₊₁NH₃]⁺, wherein 1≦n≦30, arylalkyl-ammonium ion and combination thereof. In another embodiment, the organic group may be the organic ammonium cation or group with its element(s) substituted with other appropriate element(s) (e.g. [C₆H₅C₂H₄NH₃]⁺ to [C₆H₄FC₂H₄NH₃]⁺). In various alternative embodiments, the halide perovskite may include metal cations such as Cs⁺, K⁺, Rb⁺.

In various embodiments, the halide perovskite films are prepared by a simple solution deposition process, which therefore makes this process more economically attractive compared to existing techniques.

Thus, in accordance with one aspect of the disclosure, a method for forming a halide perovskite compound is disclosed herein. The method includes dissolving RX and MX₂ in a solvent to form a precursor solution. R in RX refers to a mono-positive organic group or inorganic cation, M in MX₂ refers to a divalent metal (e.g. lead (Pb), tin (Sn), copper (Cu)) and X in RX and MX₂ refers to a halogen such as iodine (I), chlorine (CI), bromide (Br), fluorine (F), or a mixture thereof.

In various embodiments, R in RX refers to an alkyl-ammonium group, arylalkyl-ammonium group.

In present context, the term “alkyl”, alone or in combination, refers to a fully saturated aliphatic hydrocarbon. In certain embodiments, alkyls are optionally substituted. In certain embodiments, an alkyl comprises 1 to 30 carbon atoms, for example 1 to 20 carbon atoms, wherein (whenever it appears herein in any of the definitions given below) a numerical range, such as “1 to 20” or “C₁-C₂₀”, refers to each integer in the given range, e.g. “C₁-C₂₀ alkyl” means that an alkyl group comprising only 1 carbon atom, 2 carbon atoms, 3 carbon atoms, etc., up to and including 20 carbon atoms. Examples of alkyl groups include, but are not limited to, methyl, ethyl, n-propyl, isopropyl, n-butyl, isobutyl, sec-butyl, tert-butyl, tert-amyl, pentyl, hexyl, heptyl, octyl and the like.

In present context, the term “arylalkyl” refers to a group comprising an aryl group bound to an alkyl group. The term “aryl” refers to an aromatic ring wherein each of the atoms forming the ring is a carbon atom. Aryl rings may be formed by five, six, seven, eight, nine, or more than nine carbon atoms. Aryl groups may be optionally substituted. A common aryl group is phenyl.

In various embodiments, the solvent used for dissolving the solutes RX and MX₂ may be a polar solvent (e.g. N,N-dimethyl formamide (DMF), dimethyl sulfoxide (DMSO) or gamma butyrylactone (GBL)). The solutes may be dissolved with or without heating. If heating is carried out, a mild heating temperature of 70° C. or lower is preferred. Further, the dissolution may be carried out with or without stirring. If stirring is carried out, conventional stirring technique such as mechanical stirrer or magnetic stirring may be employed.

In one embodiment, the halide perovskite compound with generic formula RMX₃ or R₂MX₆ is a three-dimensional halide perovskite.

In another embodiment, the halide perovskite compound with generic formula R₂MX₄ or RMX₄ is a two-dimensional (or layered) perovskite.

The method further includes depositing the precursor solution onto a substrate, followed by heating the deposited precursor solution to form a film of the organic lead halide perovskite compound.

In various embodiments, the depositing step may include drop-casting, spin-coating, or dip-coating, thereby rendering the method solution-processable. Solution processed halide perovskite materials provide simple and inexpensive alternatives of material for potential spintronic applications as compared to traditional inorganic semiconductor systems that are produced with expensive molten-melt and gas-phase methods. This new kind of material also can be easily integrated with existing silicon based electronics.

Compared to traditional semiconductor materials, the thus-formed perovskites also possess much stronger coupling, shown by ultra-strong TRFR signal demonstrated in CH₃NH₃PbI₃ (to be elaborated in Example 1 below). Comparatively, this value (˜10°/μm in an ultrathin layer of 70 nm) is higher than that for a conventional 0.5 μm thick bismuth iron garnet film (Bi₃Fe₅O₁₂) which has record values of ˜6°/μm. The low temperature of processing also enables integration of these materials on to flexible substrates. Meanwhile, the Rabi splitting demonstrated in (C₆H₅C₂H₄NH₃)₂PbI₄ (to be elaborated in Example 2 below) at room temperature is stronger than the Rabi splitting in MBE-grown GaAs/AlGaAs multiple quantum well at cryogenic temperature. This splitting can be further improved by integration with photonic cavity. Such strong light-matter coupling and optical spin manipulability in this material class offers wider prospect for applications, for instance, in opto-spintronic applications of ultrafast optical spin switches.

Therefore, in accordance with another aspect of the disclosure, it is herein disclosed a spintronic device comprising a spintronic material, wherein the spintronic material comprises a halide perovskite compound formed according to the solution-processable method described in the earlier aspect.

The substrate onto which the precursor solution is deposited may be flexible or rigid. In preferred embodiments, the substrate is flexible.

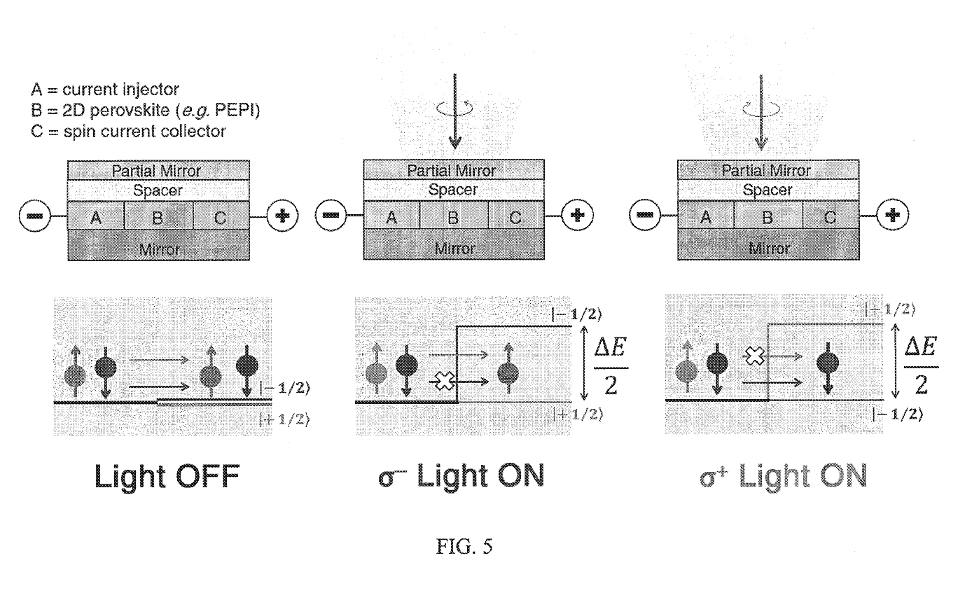

The spintronic device disclosed herein finds wide use in the applications such as quantum computing, ultrafast spin-switches, spin-polarized laser and light emitting devices, and spin-transistor. The giant faraday rotations present in the present spintronic material find its use as ultrathin/compact amplitude modulators in optical isolators, optical circulators required for optical telecommunication or laser implications or as sensing elements for remote sensing of magnetic fields. Large spin-selective Rabi splitting may find its application in optically-gated spin-transistors (FIG. 5).

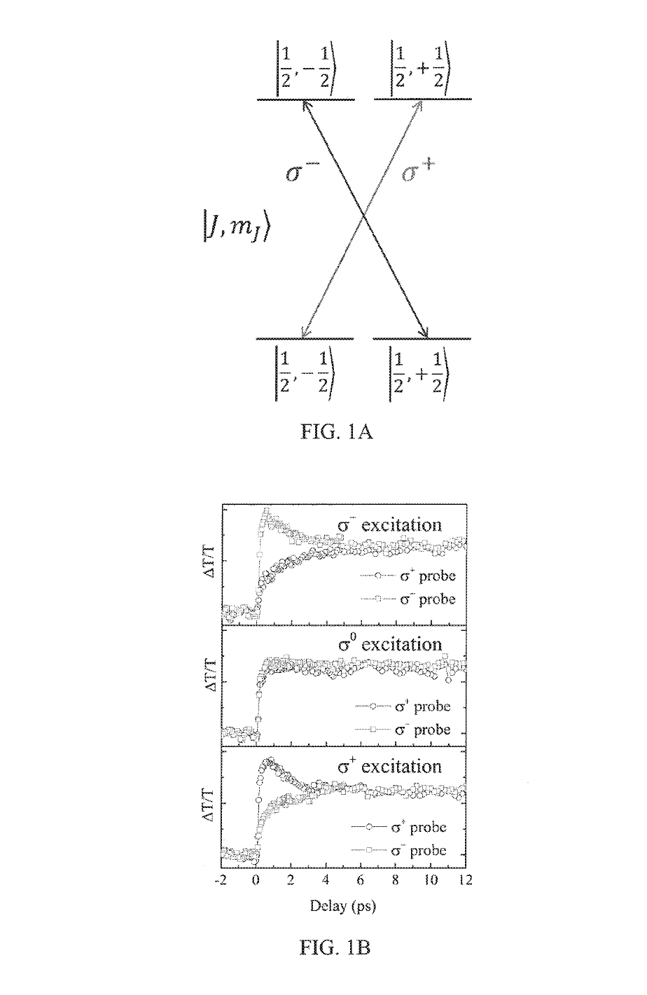

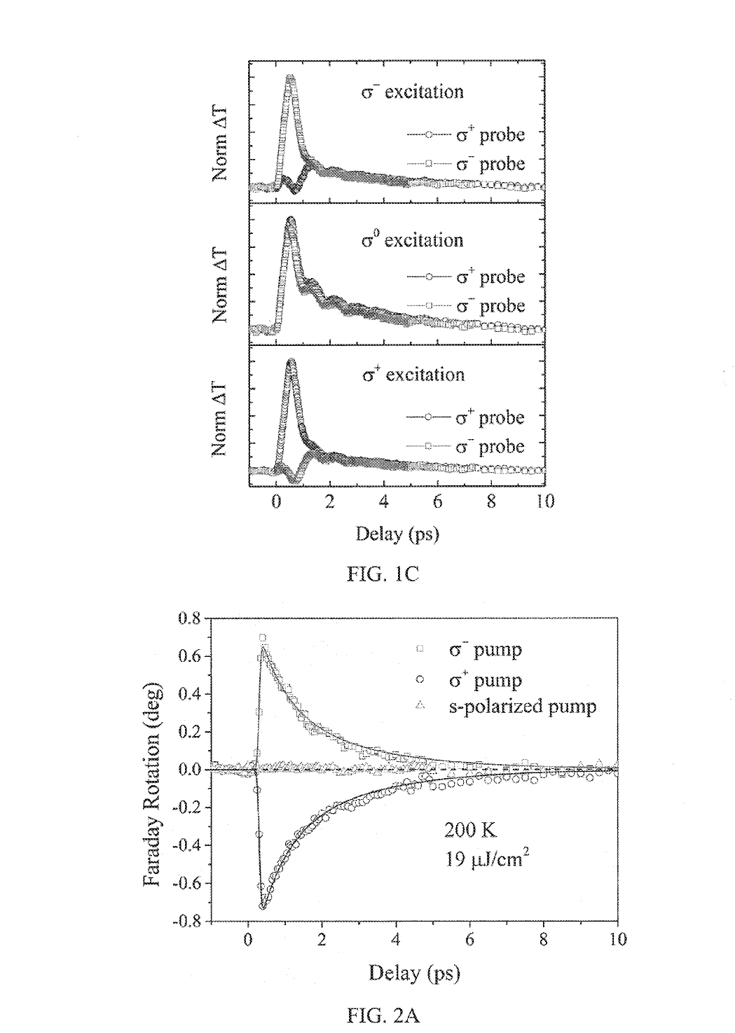

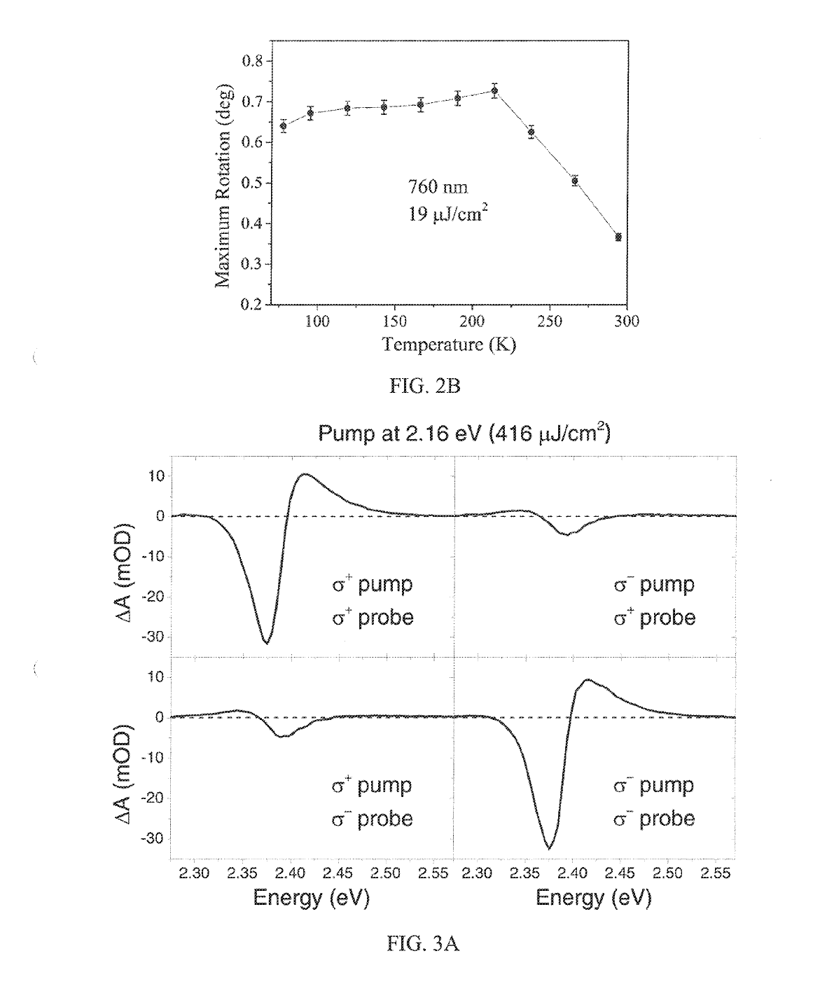

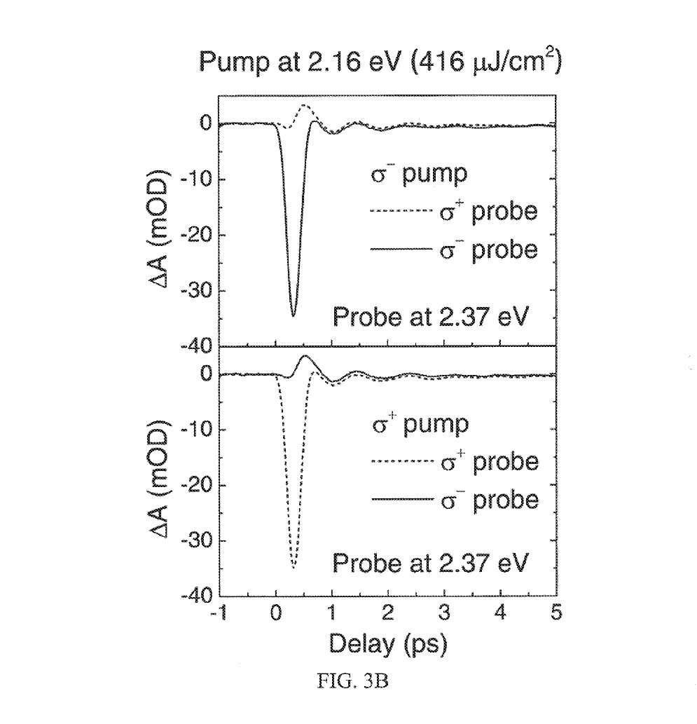

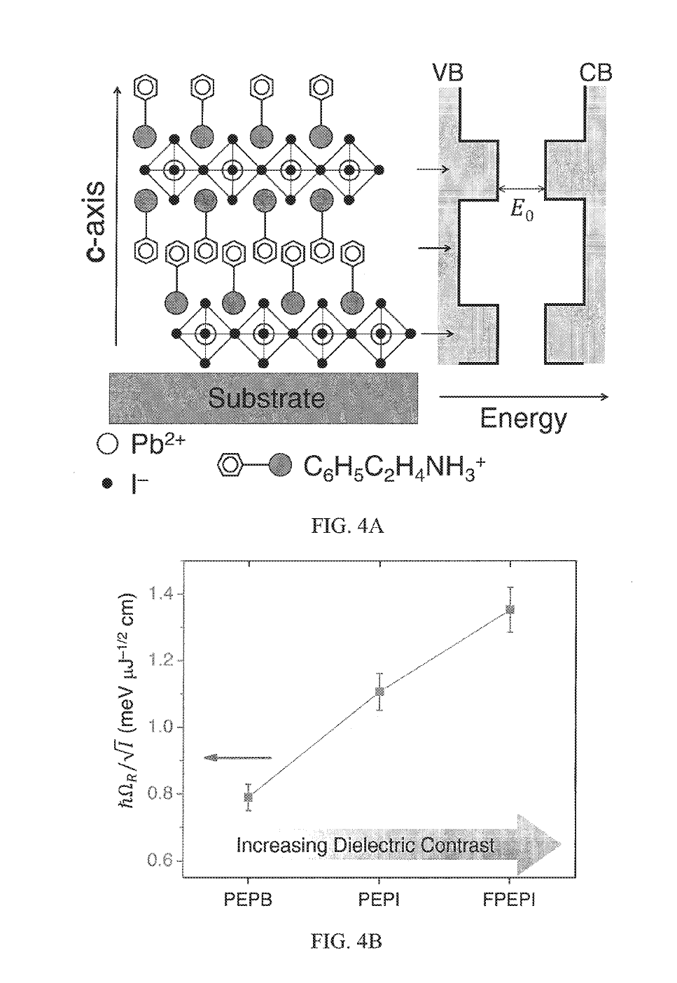

Presently disclosed class of halide perovskite materials allows manipulation of their properties to suit various applications and purposes. Specifically, their unique features include:
(a) Optical Spin Injection
   One special feature of halide perovskite material class (especially for Pb- and Sn-based perovskite) is its relatively strong spin-orbit coupling (SOC) which lifts the degeneracy of its L=1 conduction band (CB) splits into two bands with total angular momentum quantum number J=½ for lower CB and J= 3/2 for upper CB, while leaving the L=0 upper valence band (VB) intact (FIG. 1A). This feature allows J-selective optical excitation due to angular momentum transfer from photon with 100% J-polarization, which also implies spin polarization of the photoexcited carrier. This applies also for both cases of three-dimensional (3D) and 2D lead halide perovskites (e.g. CH₃NH₃PbI₃ and (C₆H₅C₂H₄NH₃)₂PbI₄, respectively) (FIG. 1B and FIG. 1C, respectively).
(b) Giant Photoinduced Faraday Rotation
   This material also possesses giant photoinduced Faraday rotation signal, for instance in lead halide perovskite CH₃NH₃PbI₃ polycrystalline thin film reaching as large as 720 milli degrees (mdeg) from an ultrathin ˜70 nm 3D (i.e., ˜10°/μm) at temperature of 200 K and wavelength (λ) of 760 nm and pump fluence of 19 μJ/cm², as shown in present experiment (FIG. 2A and FIG. 2B). Such strong coupling between the material and light allows material manipulation through optical means.
(c) Large Spin-Selective Optical Stark Effect at Room Temperature
   Relatively strong spin-selective optical Stark effect (OSE) is observed in the 2D family of this material. One example is in (C₆H₅C₂H₄NH₃)₂PbI₄, which shows a spin-selective blue shift of exciton energy level (at 2.40 eV) due to intense circularly polarized pump with energy lower than the gap (at 2.16 eV). This OSE signature is observed in transient absorption spectrum with spin-selectivity dependent on pump helicity (FIG. 3A and FIG. 3B). In the case of (C₆H₅C₂H₄NH₃)₂PbI₄ and (C₆H₄FC₂H₄NH₃)₂PbI₄ the exciton spin-states splitting can reach ˜4.5 meV and ˜6.3 meV, respectively, with pump energy 0.24 eV (1.66 mJ/cm²) below the absorption peak at room temperature. This energy splitting corresponds to ˜47 meV and ˜55 meV of Rabi splitting, respectively.
(d) Facile Material Properties Tuning
   There is possibility of tuning the material electronic properties (e.g. SOC, band-gap, etc.) through facile substitution of the elements in the perovskite, to fit the purpose of a specific application. For instance, in the case of 2D lead halide perovskite, e.g. (C₆H₅C₂H₄NH₃)₂PbI₄, which forms natural multiple quantum well system with the organic and inorganic layer as the barrier and the well, respectively (FIG. 4A), the light-matter coupling strength of such system can easily be tuned through facile substitution of the organic cation (from C₆H₅C₂H₄NH₃⁺ to C₆H₄FC₂H₄NH₃⁺) or halide anion (from F⁻ to Br⁻), due to the change of dielectric contrast between the barrier and the well (FIG. 4B). In the case of 3D halide perovskite, substituting lead (Pb) to tin (Sn) is expected to reduce the SOC.
(e) Possibility of Electrical Spin Injection
   Solution processed halide perovskite, especially 3D perovskite CH₃NH₃PbI₃, has also been proven to have low trap-states density and possesses long range balanced electron and hole diffusion lengths, which guarantee the good electron and hole injection and transport properties. Similarly, field-effect-transistor using 2D perovskite as transport material has also been previously realized. It is therefore possible to achieve efficient spin-polarized carrier injection in this material class for various purposes, i.e. spin-transport, spin-polarized lasing, etc.
(f) Low cost fabrication
   This class of materials is fabricated using a low temperature solution processed approach. In contrast, traditional semiconductor gain media are usually produced at elevated temperatures and using high vacuum growth techniques that require significant infrastructural investments.
(g) Versatile application
   A solution processable material has much greater versatility than traditional material for integration with existing silicon based technologies. It can be applied to a much wider range of device designs and substrates by simply spin-coating, dip-coating or drop-casting.

In order that the invention may be readily understood and put into practical effect, particular embodiments will now be described by way of the following non-limiting examples, specifically 3D CH₃NH₃PbI₃ and 2D (C₆H₅C₂H₄NH₃)₂PbI₄ perovskites.

### Example 1

### Highly Spin-polarized Carrier Dynamics and Ultra-large Photoinduced Magnetization in 3D CH₃NH₃PbI₃ Perovskite Thin Films

Low temperature solution-processed organic-inorganic halide perovskite CH₃NH₃PbI₃ has demonstrated great potential for photovoltaics and light emitting devices. Recent discoveries of long ambipolar carrier diffusion lengths and the prediction of the Rashba effect in CH₃NH₃PbI₃, that possesses large spin-orbit coupling, also point to a novel semiconductor system with highly promising properties for spin-based applications. Through circular pump-probe measurements, it is herein demonstrated that highly polarized electrons of total angular momentum (J) with an initial degree of polarization Pᵢₙᵢ˜90% (i.e. −30% degree of electron spin polarization) can be photogenerated in perovskites. Time-resolved Faraday rotation measurements reveal photoinduced Faraday rotation as large as 10°/μm at 200 K (at wavelength λ=750 nm) from an ultrathin 70 nm film. These spin polarized carrier populations generated within the polycrystalline perovskite films, relax via intraband carrier spin-flip through the Elliot-Yafet mechanism. Through a simple two-level model, it is elucidated the electron spin relaxation lifetime to be ˜7 ps and that of the hole is ˜1 ps. Present work highlights the potential of CH₃NH₃PbI₃ as a new candidate for ultrafast spin switches in spintronic applications.

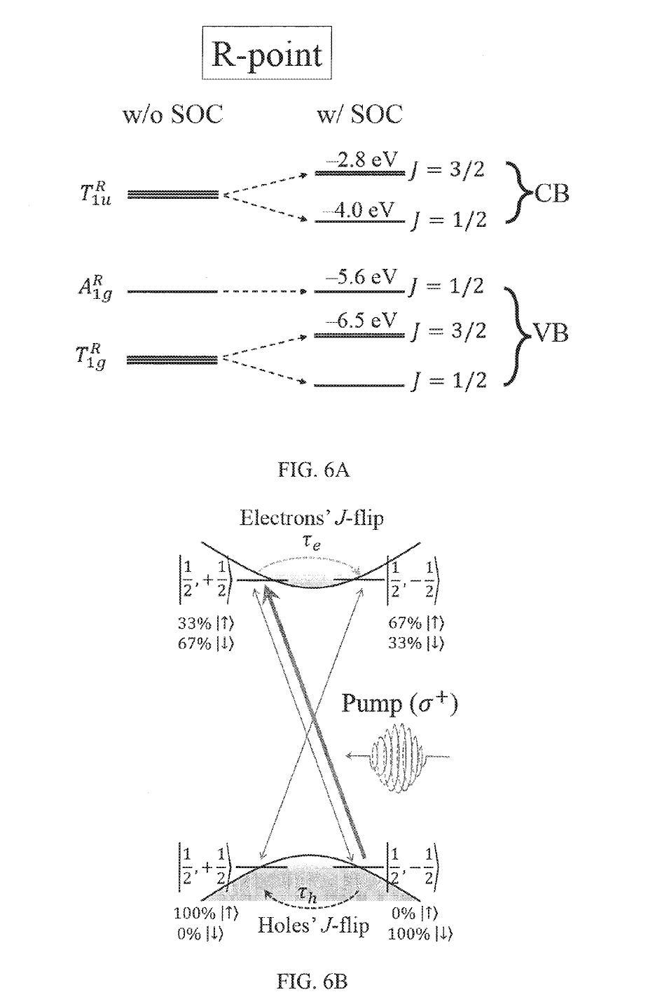

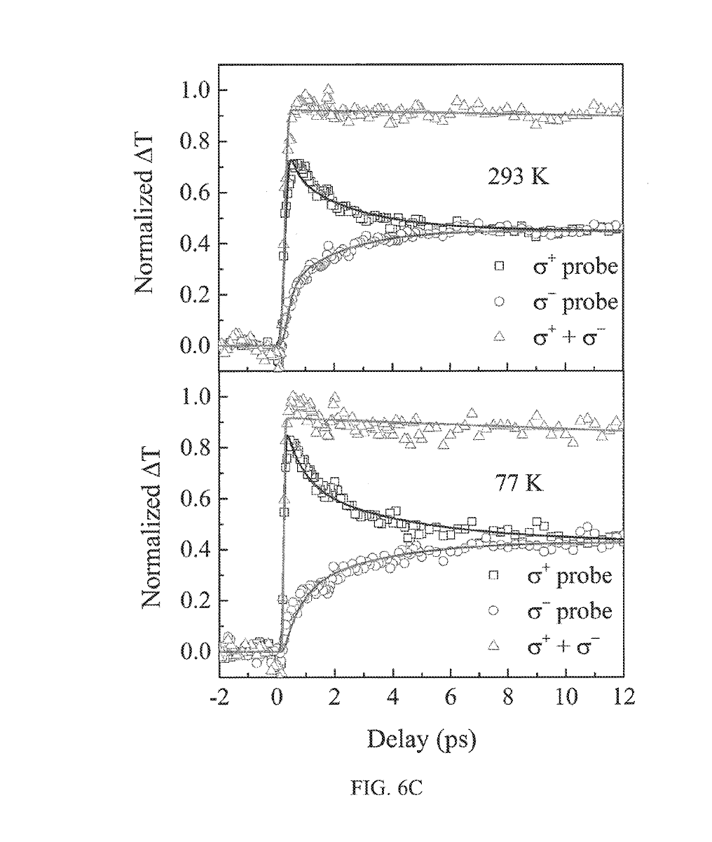

Spin relaxation lifetimes are typically described using the characteristic times of T₁ (also known as longitudinal spin relaxation time or spin-lattice relaxation time) and T₂* (also known as ensemble transverse spin relaxation time or spin decoherence time). Herein, the inventors focus on elucidating T₁ using circular pump-probe techniques without any external applied magnetic field. From earlier studies, it has been shown that in the absence of SOC, CH₃NH₃PbI₃ would have a direct bandgap at R point which consist of a six-fold degenerate J=½ and 3/2 (L=1) conduction band (CB) and doubly degenerate J=½ (L=0) upper valence band (VB). However, with SOC, the CB is split into a doubly degenerate lower J=½ band (˜1.6 eV from the VB maximum—which corresponds to the bandgap) and an upper four-fold degenerate J= 3/2 band (˜2.8 eV from the VB maximum), where J is the total angular momentum quantum number. The upper VB is however unaffected by the SOC (FIG. 6(a). Here, it is limited in present study to near bandgap excitation, i.e. the upper VB and lower CB.

From this band-structure, it is envisaged that instantaneous excitations of near 100% J-polarized populations of carriers (constituting about −33% spin-polarized electrons—see discussion below) in CH₃NH₃PbI₃ can be generated using 1.65 eV left circularly-polarized pump pulses (σ⁺ₚᵤₘₚ, by the spectroscopists' convention of being from the receiver's/detector's point of view) resonantly tuned above CH₃NH₃PbI₃'s direct bandgap of 1.63 eV. The negative sign for the electrons degree of polarization indicates a spin polarization alignment counter-polarized to the direction of injected angular momentum + (see details below). As the σ⁺ photon carries an angular momentum of + (in the direction of propagation), the absorption of such a photon will raise the angular momentum by + (Δmⱼ=+1), in accordance with total angular momentum conservation. While the circularly polarized pump defines the spin orientation of the carriers in the sample, each probe polarization will trace the different mⱼ states. In the later part, these mⱼ=±½ states will be referred as “J-states”. Tracking the changes to the J-polarized carrier populations in time with left (σ⁺_{probe}) or right (σ⁻_{probe}) circularly polarized probe pulses will allow the inventors to elucidate the dynamics of the electron/hole angular momentum flip and also model these dynamics with a simple two-level system. Note that mⱼ=+½(−½) state in the CB corresponds to 1:2 mixtures of spin states with azimuthal number mₛ=+½ and −½ (−½ and +½); while the J-states are same as the spin states (mⱼ=mₛ) for the VB, as shown by Eq. (1):

$$\vert L , S , J , {m}_{j} 〉 = {\sum }_{{m}_{j}} {\sum }_{{m}_{s}} 〈 L , S , {m}_{i} , {m}_{s} \vert L , S , J , {m}_{s} 〉 \vert L , S , {m}_{i} , {m}_{s} 〉 \\ {\vert 1 , 1 \text{/} 2 , 1 \text{/} 2 , \pm 1 \text{/} 2 〉}_{CB} = ∓ \sqrt{\frac{1}{3}} \vert 1 , 1 \text{/} 2 , 0 , \pm 1 \text{/} 2 〉 \pm \sqrt{\frac{2}{3}} \vert 1 , 1 \text{/} 2 , \pm 1 , ∓ 1 \text{/} 2 〉 \\ {\vert 1 , 1 \text{/} 2 , 1 \text{/} 2 , \pm 1 \text{/} 2 〉}_{VB} = \vert 0 , 1 \text{/} 2 , 0 , \pm 1 \text{/} 2 〉 . \qquad ( 1 )$$

This can be deduced from the Clebsch-Gordan coefficients for a system with L and S coupling. It is shown that the electron's degree of spin-polarization is −⅓ of electron's degree of J-polarization in CB; while for hole in VB, J=S.

Present findings reveal that the highly J-polarized electrons relaxes within 10 ps, while the holes relax on a much faster 1 ps timescale in the polycrystalline CH₃NH₃PbI₃ thin film. It is noted that since each J-state comprises a unique ratio of the spin-states, J-state relaxation also represents spin-state relaxation (see details below). Temperature dependent and pump fluence dependent measurements indicate that the dominant J-states relaxation channel is the intraband spin-flip through Elliot-Yafet (EY) mechanism. Time-resolved Faraday rotation measurements uncovered a high degree of photoinduced Faraday rotation as large as 720 milli-degrees (at wavelength, λ=750 nm) from a 70 nm (±10 nm) ultrathin CH₃NH₃PbI₃ polycrystalline film (i.e., corresponding to 10°/μm±2°/μm, proportional to J-polarization). Comparatively, this value is higher than that for a 0.5 μm thick bismuth iron garnet (Bi₃FesO₁₂) film which is ˜6°/μm at λ=633 nm. These findings highlight the potential of CH₃NH₃PbI₃ for application as ultrafast spin switches in spintronic.

Present samples comprise 70±10 nm-thick solution-processed CH₃NH₃PbI₃ films spin-coated on a quartz substrate. Details on the sample preparation and thickness measurements can be found below. Temperature and fluence dependent degenerate pump-probe at 750 nm (1.65 eV) slightly above the absorption band edge (˜1.63 eV) were performed using ˜50 fs laser pulses, with both pump and probe focused into ˜260 m diameter spot. Three different pump polarizations were used for each measurement (right circular σ⁻, linear σ⁰ and left circular σ⁺) to verify the observation of J-states dynamics, while the linear probe polarization was then separated into two equal components of left and right circular polarization by a quarter wave-plate and Wollaston prism for separate detection. Each probe polarization will trace the different J-states. Experimental details and the verifications on the circular pump-probe setup can also be found below.

To gain more insights into the non-equilibrium J-states relaxation mechanism and to decouple the electron and hole J-relaxation times, the inventors utilize a kinetic model based on a two-level system as shown in FIG. 6B. The population kinetics of the electrons (holes) in a given |J, m_{J} [symbol] state in conduction (valence) band can be described by the following rate equation:

$$\frac{d}{d t} {f}_{e , h}^{\vert 1 \text{/} 2 , \pm 1 \text{/} 2 〉} = A ( \frac{1 \pm p}{2} ) {e}^{- {t}^{2} \text{/} {τ}_{0}^{2}} - \frac{{f}_{e , h}^{\vert 1 \text{/} 2 , \pm 1 \text{/} 2 〉} - {f}_{e , h}^{\vert 1 \text{/} 2 , ∓ 1 \text{/} 2 〉}}{{τ}_{e , h}} - \frac{{f}_{e , h}^{\vert 1 \text{/} 2 , \pm 1 \text{/} 2 〉}}{{τ}_{c}} \qquad ( 2 )$$

where ƒₑ^{|1/2±1/2)} (ƒₕ^{|1/2±1/2)}) denotes electrons (holes) occupation probability for a given electron |J,m_{J} [symbol] -state in CB (VB), τ₀ is laser temporal pulse width parameter (Gaussian pulse), p is the excitation degree of polarization which is equal to 1 for pure circular excitation as in present case, τₑ (τₕ) is the electrons (holes) J relaxation time, i.e., intraband interstates transfer time or ‘J-flip’ (correspond to spin-flip), which is related to T₁ through 2T₁=τ_{e,h}, and τₑ is the spin-independent carrier relaxation time. Here, T₁ can be related to J relaxation time because J-polarization is directly proportional to the spin-polarization; hence they share identical relaxation times. It is noted that ƒₕ^{|1/2±1/2)} in VB refers to the hole state with mⱼ=±½. Due to the dynamics of state filling, the pump-probe signal is proportional to the sum of the electron and hole occupation populations, which can be written as:

$${( \frac{Δ T}{T} )}_{\pm \frac{1}{2}} ∝ {f}_{e}^{\pm \frac{1}{2}} + {f}_{h}^{∓ \frac{1}{2}} . \qquad ( 3 )$$

Eqn. 2 can be solved analytically to obtain the following fitting function:

$${( \frac{Δ T}{T} )}_{\pm \frac{1}{2}} ∝ {e}^{- t \text{/} {τ}_{c}} \{ [ 1 + erf ( \frac{t}{{τ}_{0}} - \frac{{τ}_{0}}{2 {τ}_{c}} ) ] \pm \frac{1}{2} {\sum }_{i = e , h} [ {e}^{{τ}_{0}^{2} \text{/} {τ}_{i}^{2}} ( 1 + erf ( \frac{t}{{τ}_{0}} - \frac{{τ}_{0}}{{τ}_{i}} ) ) {e}^{- 2 t \text{/} {τ}_{i}} ] \} . \qquad ( 4 )$$

The experimental data is then globally fitted (simultaneously) by using eqn. 4 with +½ and −½ for σ⁺ and σ⁻ probe signal respectively, to obtain the shared fitting parameter values. It is noted that when the signal from σ⁺ probe and σ⁻ probe are added up, the result will be the total number of carriers in both J-states and is independent of the pump polarization as shown in eqn. 5:

$${( \frac{Δ T}{T} )}_{+ \frac{1}{2}} + {( \frac{Δ T}{T} )}_{- \frac{1}{2}} ∝ [ 1 + erf ( \frac{t}{{τ}_{0}} - \frac{{τ}_{0}}{2 {τ}_{c}} ) ] {e}^{- t \text{/} {τ}_{c}} \qquad ( 5 )$$

FIG. 6C shows that the experimental data (at 293 K and 77 K) for σ⁺ pump excitation (with fluence of 19 μJ/cm²) are well-fitted using eqn. 4. Following σ⁺ pump excitation, the σ⁺ probe signal first exhibits a sharp rise (indicating a large photoexcited population of electrons in the mⱼ=+½ J-state), which then proceeds with a decay of the signal to equilibrium (signifying the depopulation of mⱼ=+½ state). Concomitantly, the a probe signal rises gradually (indicating the filling of mⱼ=−½ state) at a rate that matches the decay of the σ⁺ probe signal. In the absence of any external magnetic field, the J-polarized electrons approach to an equilibrium with 50% ‘J-up’ (mⱼ=+½ state) and 50% ‘J-down’ (mⱼ=−½ state). These equalized populations of electrons and holes eventually undergo carrier recombination on a nanosecond timescale typical for the CH₃NH₃PbI₃ system. The sum of the σ⁺ and σ⁻ probe signals, which shows a sharp rise and continued by an approximately constant value within the measurement time window, is also well-fitted Eq. (5)—thus validating the preceding discussion on the total number of photoexcited carriers. This result clearly shows that the J state-relaxation occurs in a timescale much shorter than the carrier recombination lifetime (τ_{e,h}<<τₑ), consistent with an intraband population transfer between the two J-states i.e., intraband angular momentum flip (J-flip). The intraband J-flip process stops after the populations between these two states are balanced.

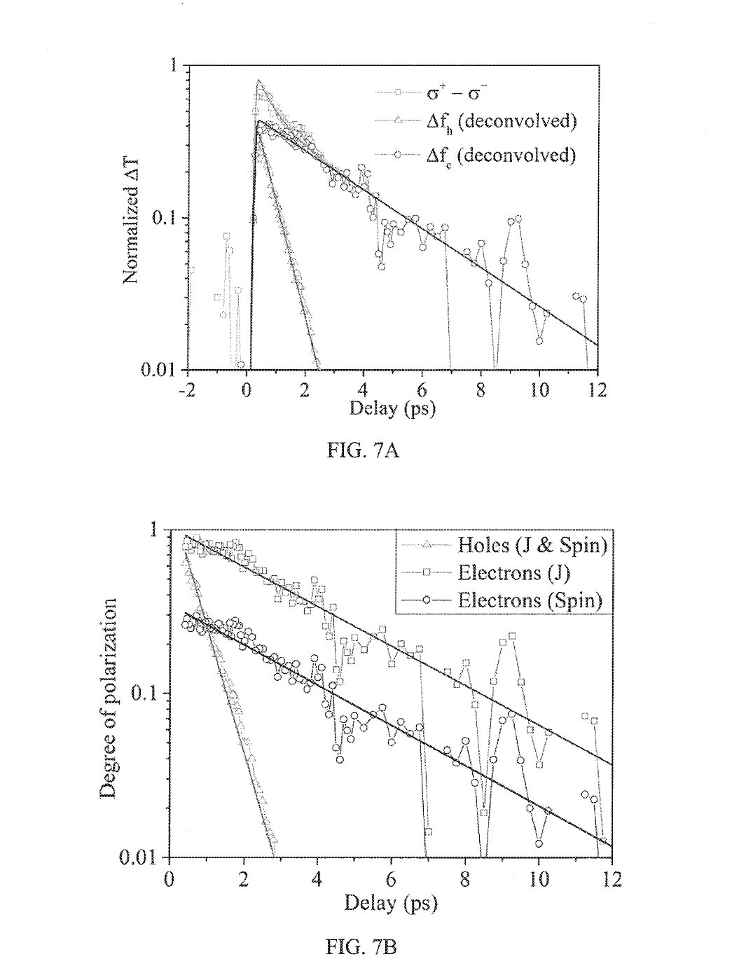

Although a 100% J-polarized signal is expected from the selection rules, the maximum σ⁺ probe signals in FIG. 6B immediately after photoexcitation is only about 70% at 293K (or ˜80% at 77K), much lower than the total carrier population (σ⁺+σ⁻). This indicates that only such fraction of the photoexcited carriers occupy the +½ mⱼ-state. The inventors attributed this to the ultrafast hole spin relaxation process, which occurs much faster than that of the electrons, and is comparable to the timescale of present excitation pulse. This is evident from the deconvolution of the electron and hole contributions at 77 K as shown in FIG. 7A (see below for details of the method). FIG. 7A shows the plots of population difference between mⱼ=+½ and mⱼ=−½ states at 77 K for both electrons (Δƒₑ=ƒₑ^{+1/2}−ƒₑ^{-1/2}) and holes (Δƒₕ=ƒₕ^{-1/2}−ƒₕ^{+1/2}) and that of the difference between the σ⁺ and σ⁻ probe signals (i.e., σ⁺−σ⁻). the latter is in fact equals to the difference between total population of mⱼ=+½ and mⱼ=−½ states of both electron and hole, i.e., Δƒ_{ƒ}+Δƒₕ. Using the common definition for degree of spin polarization (η), it is defined the parameters:

$${η}_{electrons} ( t ) = \frac{{N}_{e ↑} - {N}_{e ↓}}{{N}_{e ↑} + {N}_{e ↓}} = - \frac{Δ {f}_{e}}{3 {f}_{e}} \\ {η}_{holes} ( t ) = \frac{{N}_{h ↑} - {N}_{h ↓}}{{N}_{h ↑} + {N}_{h ↓}} = \frac{Δ {f}_{h}}{{f}_{h}} \qquad ( 6 )$$

for electrons and holes—plotted in FIG. 7B, for a time delay 0.5 ps after laser excitation where the signal rise is cut off (to minimize the effects of backscattered laser light from the sample). N_{↑} and N_{↓} denotes the population of spin-up (ms=+½) and spin-down (ms=−½) respectively. From the figure, the initial degree of electrons spin polarization Pᵢₙᵢ is about −30% (90% J-polarization), which agrees with the initial expectation. The electron spin decays on a much longer time scale of 7±1 ps compared to that of the holes 1.1±0.1 ps.

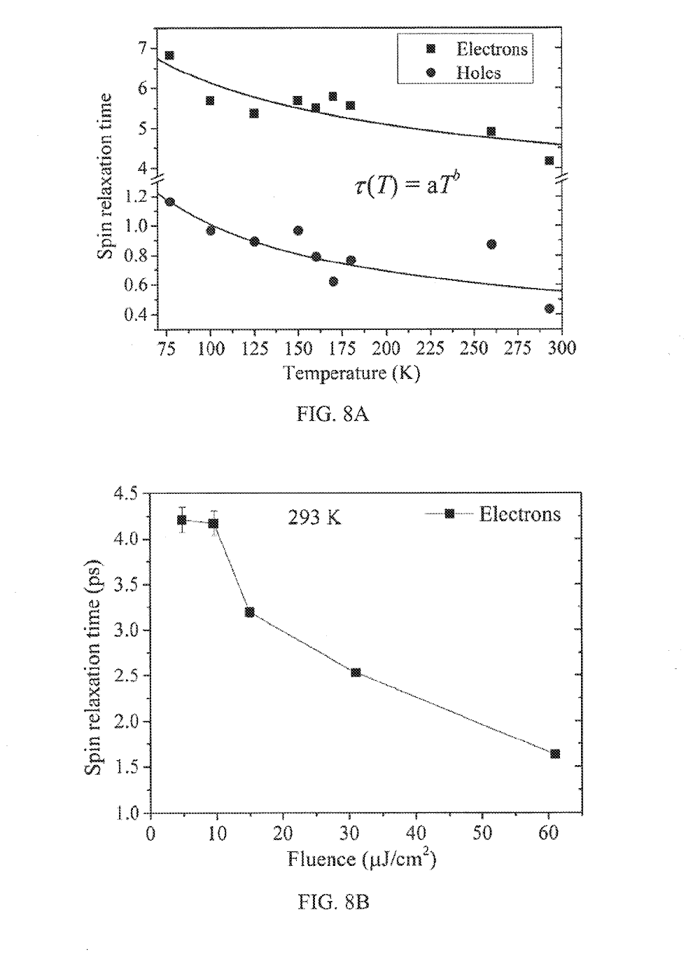

Circular pump probe measurements were also performed as a function of temperature and fluence to elucidate the J-relaxation mechanism (corresponds to spin-relaxation and has identical relaxation time). FIG. 8A shows temperature dependence of spin relaxation time for both electrons and holes, obtained from fits using eqn. 4 (within ±10% accuracy) at a pump fluence of 19 μJ/cm². The result shows that for electrons the spin relaxation time generally decreases with increasing temperature, but exhibits a weak dependence on temperature as the spin lifetimes decreases by factor ˜1.6 across the temperature range. Although the holes spin relaxation time show a similar decreasing trend with temperature, it is in fact more susceptible to temperature effects (as the decrease is about two times larger).

Amongst the three possible spin relaxation mechanisms, only the Elliott-Yafet (EY) mechanism is most probable for CH₃NH₃PbI₃. The D'yakonov-Perel' (DP) mechanism, which is applicable to systems without inversion symmetry, is irrelevant because the CH₃NH₃PbI₃ crystal structure exhibits inversion symmetry. The Bir-Aronov-Pikus (BAP) mechanism, which is applicable to heavily p-doped semiconductor, is also unlikely since the present sample does not contain significant amounts of p-doping. Moreover, BAP relaxation rate depends on the exchange interaction between electrons and holes which generally can be characterized through the exchange (hyperfine) splitting of excitonic ground state. However this splitting has never been observed in CH₃NH₃PbI₃, plausibly because it is very weak. Hence, it is believed that in the present case, BAP does not play an important role in the spin-flip processes.

From its weak dependence on temperature, it is inferred that the spin relaxation occurs mainly through Elliott-Yafet (EY) impurities and grain boundaries scattering. The inventors substantiate this assignment with the power fits of τ α T^{b} for spin relaxation time vs temperature, where it is obtained b=−0.27±0.06 for electrons and b=−0.55±0.15, which is close to the theoretical prediction τ α T^{1/2} of EY mechanism for scattering by charged impurities. FIG. 8B shows the fluence dependent electrons spin relaxation time measurement as function of pump fluence at 293 K. It is noted that holes spin relaxation time at high fluence is shorter the present temporal resolution. The result shows a strong dependence with decreasing trend of spin relaxation time with the increasing fluence especially at high fluence, which implies that carrier-carrier scattering also contributes to the spin relaxation process. As the spin flip process originates mainly from carriers, impurities and grain boundaries scattering, longer spin diffusion lengths can be expected from vacuum-deposited CH₃NH₃PbI₃ samples at room temperatures, instead of solution-processed samples in this work. Furthermore, it should also be feasible to tune the SOC through the replacement of the A cation, i.e., Pb with other transition metals such as Cu (copper) and Sn (tin). This could possibly lead to longer spin diffusion lengths at room temperatures.

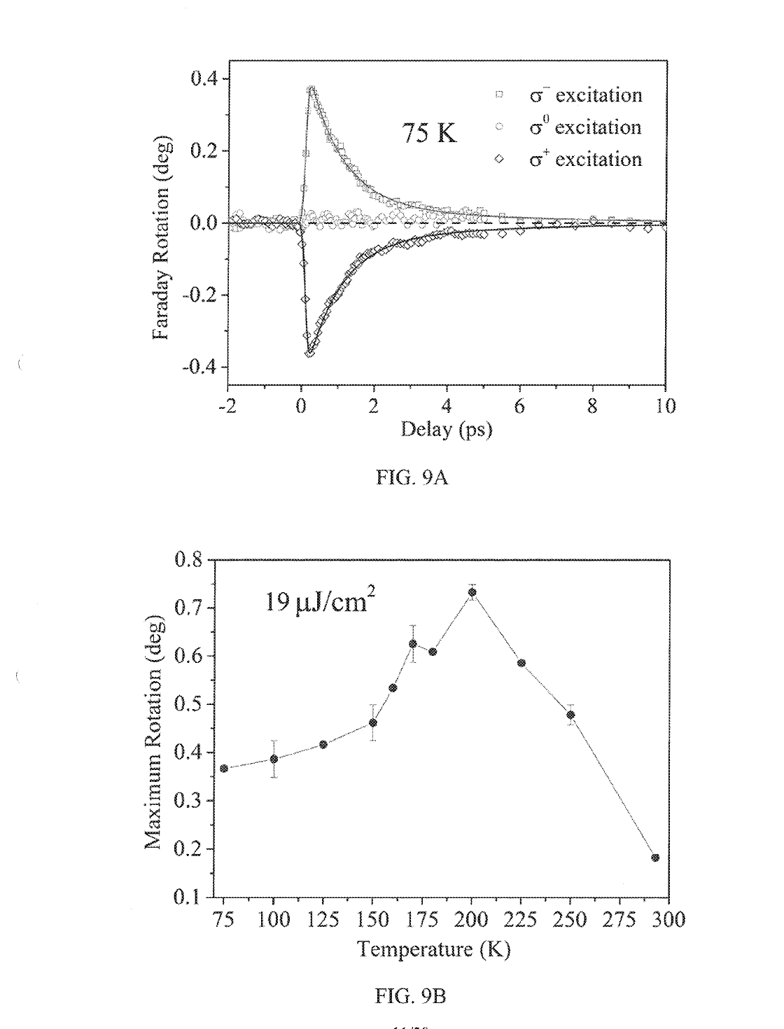

Lastly, time-resolved Faraday rotation (TRFR) measurements as a function of temperature (in zero magnetic field) were also performed to examine the photoinduced magnetization from the CH₃NH₃PbI₃ thin films. FIG. 9A shows a typical pump-induced Faraday rotation signal taken at 75 K for σ⁺, σ⁻ and σ⁰ (linear) pump excitations at 750 nm wavelength. Details on the TRFR setup and measurements are given below. The sign inversion of the Faraday rotation signals for opposite circular polarizations of the pump beam and null signal from the linear pump excitation help validate that the photoinduced magnetization is observed. Here, the rotation angle is proportional to sample's magnetization, which originates from the photoinduced carrier J-polarization (i.e. αΔƒₑ+Δƒₕ). No signal was observed from blank quartz substrate. Bi-exponential fitting yields the lifetimes τ₁=0.9±0.1 ps (holes) and τ₂=4±1 ps (electrons), which are consistent with the values obtained from the J-flip (or spin-flip) measurements (τₕ=˜1.1 ps for holes and τₑ=˜7 ps for electrons). Note that magnetization lifetime is expected to be half of spin-flip lifetime, since it measures the population difference between both spin states, which doubles the rate (for details see below).

It is remarkable that a very large pump-induced Faraday rotation of ˜720 milli-degrees (mdeg) at 200 K is obtained from these nanometric thick (i.e., 70±10 nm) CH₃NH₃PbI₃ films (i.e., 10°/μm±2°/μm) (FIG. 9B). Comparatively, this value is higher than that for a 0.5 μm thick bismuth iron garnet film (Bi₃Fe₅O₁₂) which has ˜6°/μm at room temperature (at wavelength 633 nm), thick drop-casted (few microns thick) colloidal CdSe quantum dots with cavity enhancement of Faraday rotation at room temperature (˜350 mdeg at wavelength 630 nm); and much higher that the ˜1 μm-thick MnSe Digital Magnetic Heterostuctures (DMH) at 5 K (˜0.6°/μm at wavelength 440-510 nm). Such ultra-large photoinduced magnetization is characteristic of the large SOC from CH₃NH₃PbI₃. Temperature dependence of the TRFR signal is given in FIG. 9B, where the trend is most likely related to the phase transitions of CH₃NH₃PbI₃.

In summary, it is herein reported on the first spin dynamics studies in CH₃NH₃PbI₃ using spin-dependent circularly-polarized pump-probe techniques. The present findings show that the J-states (or spin) relaxation in CH₃NH₃PbI₃ occurs through intraband (J-flips) spin flips within 10 ps (for electrons) and 1 ps (for holes) as validated by a simple two-state model. The dominant spin relaxation is believed to be the EY impurities scattering mechanism. TRFR measurements uncovered a high degree of photoinduced Faraday rotation as large as 720 mdeg from an ultrathin ˜70 nm CH₃NH₃PbI₃ polycrystalline thin film (i.e., 10°/μm±2°/μm). Comparatively, this value is much higher than that for magnetic heterostuctures of equivalent thicknesses. Importantly, this work highlights the potential of CH₃NH₃PbI₃ as a new candidate for spintronic applications especially as ultrafast spin switches. While current findings suggest limitations in solution-processed CH₃NH₃PbI₃ thin-film for spin-transport purposes due to fast spin relaxation, nevertheless there are possibilities to overcome such shortcomings through improvements in sample preparation techniques, e.g., vacuum deposition, or through materials engineering, e.g., both cation and anion replacement in such perovskites which could be further explored as means to tune the SOC.

### Sample Preparation

Quartz substrates were cleaned by ultrasonication for 30 minutes in acetone and ethanol respectively, followed by UV ozone treatment for 10 minutes. A 10 wt % solution of equimolar lead iodide (purchased from Alfa Aesar) and methylammonium iodide (DyeSol) in dimethylformamide (Sigma Aldrich) was prepared and stirred overnight at 70° C. The resulting CH₃NH₃PbI₃ precursor solution was spin coated on the quartz substrates at 4000 rpm for 30 seconds. The films were then heat treated at 100° C. for 5 minutes. Solution preparation, spin coating and heat treatment were done in dry nitrogen environment.

### Sample Thickness Measurement

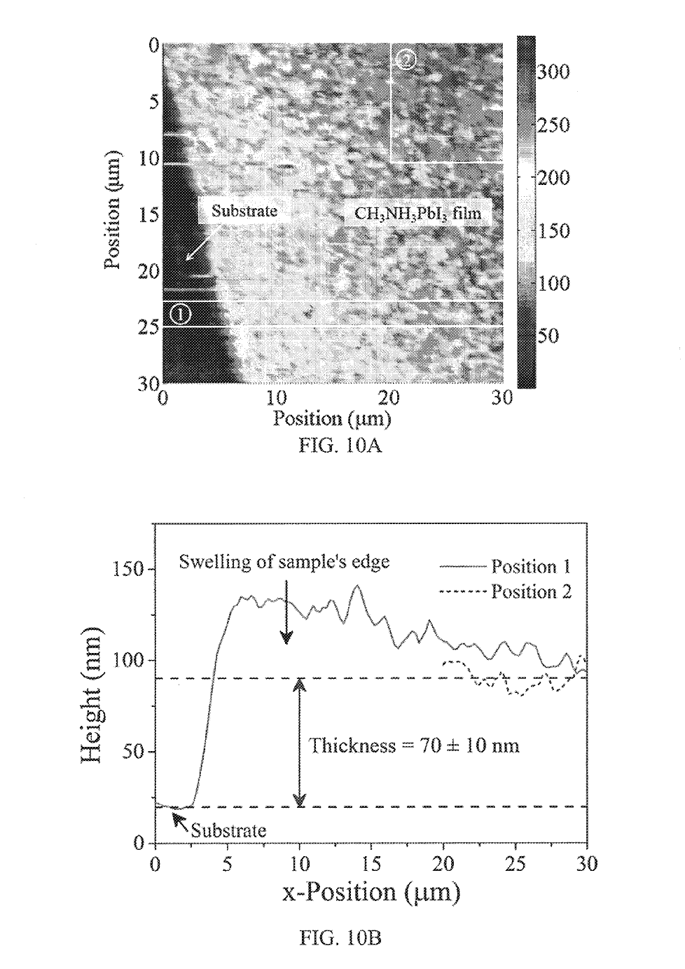

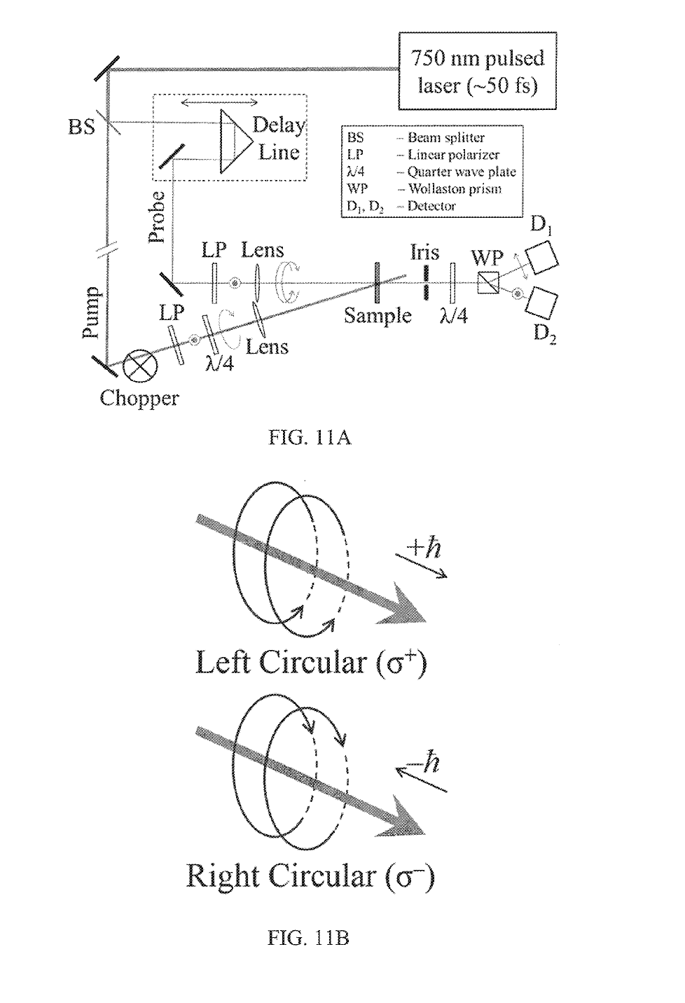

The sample thickness was measured using an atomic force microscope (AFM) where the image is shown in FIG. 10A-B. The middle of the thin film was mechanically scratched to create an edge for measurement. The film thickness obtained is 70±10 nm (over 10×10 μm² area).

### Band Structure, J-State, and Spin-State Analysis

FIG. 6A shows the DFT calculation of the band structure of CH₃NH₃PbI₃ at R-point where the bandgap is located. The VB originates mainly from contributions from the Pb(6s)I(5p) orbitals, while the CB comes mainly from Pb(6p) orbitals. Due to spin-orbit coupling (SOC), the CB (L=1) is split into lower J=½ state and upper J= 3/2 states, while leaving the VB (L=0) almost unaffected. As the emphasis of this example is at the band-edge dynamics, the discussion will focus on the top-most VB (J=S=½) and bottom-most CB (J=½). Both bands are doubly degenerate (mⱼ=±½). The contribution of spin-states can be predicted from the Clebsch-Gordan (CG) coefficients:

$$\vert L , S , J , {m}_{j} 〉 = {\sum }_{{m}_{i}} {\sum }_{{m}_{s}} 〈 L , S , {m}_{i} , {m}_{s} \vert L , S , J , {m}_{s} 〉 \vert L , S , {m}_{i} , {m}_{s} 〉 \qquad ( 7 )$$

where S=½ (electron's spin), and L=1 for CB and L=0 for VB (orbital angular momentum). The CG coefficient is zero if mⱼ≠mₛ+mₗ while the non-zero component can be obtained from CG table for the addition of angular momenta. For CB, the two states (mⱼ=+½) are given by:

$${\vert 1 , 1 \text{/} 2 , 1 \text{/} 2 , + 1 \text{/} 2 〉}_{CB} = - \sqrt{\frac{1}{3}} \vert 1 , 1 \text{/} 2 , 0 , + 1 \text{/} 2 〉 + \sqrt{\frac{2}{3}} \vert 1 , 1 \text{/} 2 , + 1 , - 1 \text{/} 2 〉 \\ {\vert 1 , 1 \text{/} 2 , 1 \text{/} 2 , - 1 \text{/} 2 〉}_{CB} = - \sqrt{\frac{2}{3}} \vert 1 , 1 \text{/} 2 , - 1 , + 1 \text{/} 2 〉 + \sqrt{\frac{1}{3}} \vert 1 , 1 \text{/} 2 , 0 , - 1 \text{/} 2 〉 \qquad ( 8 )$$

while for VB:

|0,½,0+½ [symbol] _{VB}=|0,½,0,+½

[symbol]

|0,½,0−½ [symbol] _{VB}=|0,½,0,−½ [symbol] (9)

where state mₛ=+½ and mₛ=−½ are spin-up and spin-down states respectively. From the equation it is clear that the ‘J-up’ (mⱼ=+½) state consists of 33% spin-up and 67% spin-down electrons, while the ‘J-down’ (mⱼ=−½) state consists of 67% spin-up and 33% spin-down electrons.

### Circularly Polarized or Spin-Dependent Pump-Probe Experimental Setup and Verifications

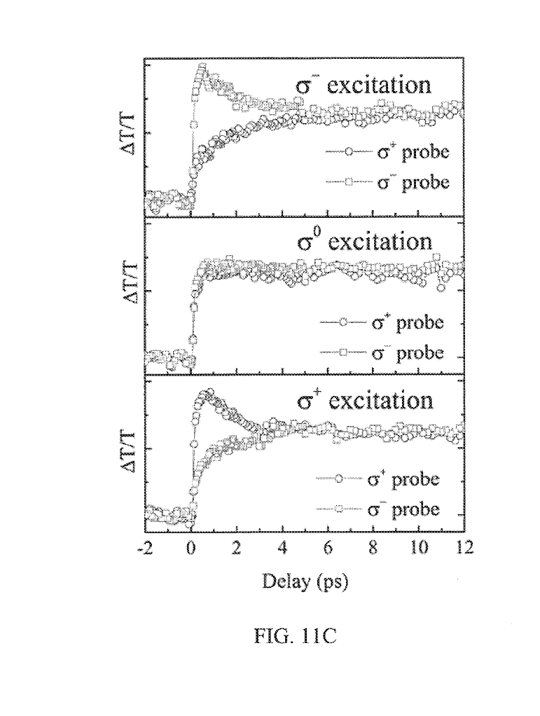

The experimental setup is given by FIG. 11A, similar to a typical degenerate pump-probe setup; with the pump polarization set to circular polarization. It is noted that it is used herein the spectroscopists' convention (receiver's/detector's point of view), where the photon with positive helicity (σ⁺), i.e., spin of + along the direction of their propagation, is defined to be left-circular. The left/right handedness is determined as seen by the receiver, where anticlockwise (clockwise) rotation of the electric field corresponds left (right) circular polarization (FIG. 11B). Probe polarization was set to linear (s-polarized), which consists of two equal components of left and right circular polarization. A quarter-wave plate (placed at 45° anticlockwise, as seen from receiver) will then convert the left-circular and right-circular component into s-polarized and p-polarized components respectively, which are then split by a Wollaston prism for separate detection by two photo-detectors. An iris is also placed on the probe line before the detection setup to minimize pump-scattering to the detectors.

With a large SOC, instantaneous (near 100%) J-polarized populations of carriers in CH₃NH₃PbI₃ can be generated using 1.65 eV left circularly-polarized pump pulses (σ⁺ₚᵤₘₚ) resonantly tuned above CH₃NH₃PbI₃'s bandgap of 1.6 eV (FIG. 6A). Due to conservation of angular momentum, both generated electrons and holes will each have angular momentum of +½ in the direction of light propagation.

FIG. 11C shows the normalized circular pump-probe transmittance data following photoexcitation with circularly polarized σ^{±} and linearly polarized σ⁰ pulses. As σ^{±} photon carries angular momentum of ±, the absorption of such a photon will raise the angular momentum is raised by ±, i.e. Δmⱼ=±1, conserving the total angular momentum. While the circularly polarized pump defines the J orientation of the carriers in the sample, each probe polarization will trace the populations of the different J-states. This is evident from FIG. 11C. When the pump polarization is switched from σ⁺ (top) and σ⁻ (bottom), the dynamics in the probe signal switch in accordance to the different optically injected angular momentum. However, when the sample is excited using linearly polarized σ⁰ pulses, the expected symmetrical probe signals are obtained (middle), due equal components of σ⁺ and σ⁻ (i.e., zero total angular momentum). Hence equal populations of carriers in both J-states are thus created. These measurements provide verification that the inventors are indeed observing the dynamics between J-states (correspond to spin dynamics) in CH₃NH₃PbI₃.

### Model Derivation and Deconvolution

The schematic of the model of the system is provided in FIG. 6B. The kinetics of each state population is given by:

$$\frac{d}{d t} {f}_{e , h}^{\vert 1 \text{/} 2 , \pm 1 \text{/} 2 〉} = A ( \frac{1 \pm p}{2} ) {e}^{- {t}^{2} \text{/} {τ}_{0}^{2}} - \frac{{f}_{e , h}^{\vert 1 \text{/} 2 , \pm 1 \text{/} 2 〉} - {f}_{e , h}^{\vert 1 \text{/} 2 , ∓ 1 \text{/} 2 〉}}{{τ}_{e , h}} - \frac{{f}_{e , h}^{\vert 1 \text{/} 2 , \pm 1 \text{/} 2 〉}}{{τ}_{c}} . \qquad ( 10 )$$

Define Δƒₑ=ƒₑ^{+1/2}−ƒₑ^{-1/2} and Δƒₕ=ƒₕ^{-1/2}−ƒₕ^{+1/2}. Having p=1 and dropping the e and h index, Eq. (10) is analytically solved to obtain:

$$Δ f ( t ) = A {e}^{{τ}_{0}^{2} \text{/} {τ}_{{s}^{′}}^{2}} \frac{{τ}_{0} \sqrt{π}}{2} {e}^{- 2 t \text{/} {τ}_{{s}^{′}}} ( 1 + erf [ \frac{t}{{τ}_{0}} - \frac{{τ}_{0}}{{τ}_{{s}^{′}}} ] ) \qquad ( 11 )$$

where 2/τ_{s′}=2/τₛ+1/τ_{c} with τₛ is the J-flip lifetime (s=e for electrons and s=h for holes). Other parameters are explained in the earlier paragraphs. It is noted that measured pump-probe signal comes from the contribution of both electron and holes. The fitting function is obtained analytically by substituting Eq. (11) back to Eq. (10) and solving the differential equation:

$${( \frac{Δ T}{T} )}_{\pm 1 \text{/} 2} = {A}^{′} {e}^{- t \text{/} {τ}_{c}} \{ 2 [ 1 + erf ( \frac{t}{{τ}_{0}} ) ] \pm {\sum }_{s = e , h} {e}^{\frac{{τ}_{0}^{2}}{{τ}_{s}^{2}}} [ 1 + erf ( \frac{t}{{τ}_{0}} - \frac{{τ}_{0}}{{τ}_{s}} ) ] {e}^{- 2 t \text{/} {τ}_{s}} \} \qquad ( 12 )$$

where +½ and −½ refers to measurement by σ⁺ and σ⁻ probe, respectively and A′ is a constant. It is noted that assumption of τ_{c}>>τₛ, τ₀ has been applied to simplify the analytical function. The difference between measured σ⁺ and σ⁻ probe signal is given by:

$${( \frac{Δ T}{T} )}_{+} - {( \frac{Δ T}{T} )}_{-} = Δ {f}_{e} + Δ {f}_{h} = 2 {A}^{′} {e}^{- t \text{/} {τ}_{c}} {\sum }_{s = e , h} {e}^{\frac{{τ}_{0}^{2}}{{τ}_{s}^{2}}} [ 1 + erf ( \frac{t}{{τ}_{0}} - \frac{{τ}_{0}}{{τ}_{s}} ) ] {e}^{- 2 t \text{/} {τ}_{s}} \qquad ( 13 )$$

where it can be separated between electrons and holes contribution:

$$Δ {f}_{e} = 2 {A}^{′} {e}^{- t \text{/} {τ}_{c}} {e}^{{τ}_{0}^{2} \text{/} {τ}_{c}^{2}} [ 1 + erf ( \frac{t}{{τ}_{0}} - \frac{{τ}_{0}}{{τ}_{e}} ) ] {e}^{- 2 t \text{/} {τ}_{c}} \\ Δ {f}_{h} = 2 {A}^{′} {e}^{- t \text{/} {τ}_{c}} {e}^{{τ}_{0}^{2} \text{/} {τ}_{h}^{2}} [ 1 + erf ( \frac{t}{{τ}_{0}} - \frac{{τ}_{0}}{{τ}_{h}} ) ] {e}^{- 2 t \text{/} {τ}_{h}} . \qquad ( 14 )$$

Using parameters obtained previously, i.e., τₑ, τₕ and τ₀, numerical value of Δƒₑ and Δƒₕ can be calculated to give the ‘theoretical’ ratio between electron and hole contribution. This ratio will then be used to deconvolve the experimental data:

$$Δ {f}_{e}^{dc} = \frac{Δ {f}_{e}}{Δ {f}_{e} + Δ {f}_{h}} \times [ {( \frac{Δ T}{T} )}_{+} - {( \frac{Δ T}{T} )}_{-} ] \\ Δ {f}_{h}^{dc} = \frac{Δ {f}_{h}}{Δ {f}_{e} + Δ {f}_{h}} \times [ {( \frac{Δ T}{T} )}_{+} - {( \frac{Δ T}{T} )}_{-} ] \qquad ( 15 )$$

where the superscript ‘dc’ indicates ‘deconvolved’. The plot of individual contribution between electron and hole to the J-relaxation can be seen in FIG. 7A. The degree of spin polarization (η) is defined classically as:

$${η}_{electrons} ( t ) = \frac{{N}_{e ↑} - {N}_{e ↓}}{{N}_{e ↑} + {N}_{e ↓}} \\ {η}_{holes} ( t ) = \frac{{N}_{h ↑} - {N}_{h ↓}}{{N}_{h ↑} + {N}_{h ↓}} \qquad ( 16 )$$

where N_{↑} and N_{↓} denotes population of spin-up (mₛ=+½) and spin down (mₛ=−½) respectively. From Eq. (8) and (9), it can be straightforwardly shown that:

$${η}_{electrons} ( t ) = \frac{( 1 \text{/} 3 {f}_{e}^{+ 1 \text{/} 2} + 2 \text{/} 3 {f}_{e}^{- 1 \text{/} 2} ) - ( 2 \text{/} 3 {f}_{e}^{+ 1 \text{/} 2} + 1 \text{/} 3 {f}_{e}^{- 1 \text{/} 2} )}{( 1 \text{/} 3 {f}_{e}^{+ 1 \text{/} 2} + 2 \text{/} 3 {f}_{e}^{- 1 \text{/} 2} ) + ( 2 \text{/} 3 {f}_{e}^{+ 1 \text{/} 2} + 1 \text{/} 3 {f}_{e}^{- 1 \text{/} 2} )} = - \frac{1}{3} \frac{Δ {f}_{e}}{{f}_{e}} \\ {η}_{holes} ( t ) = \frac{{f}_{h}^{+ 1 \text{/} 2} - {f}_{e}^{- 1 \text{/} 2}}{{f}_{h}^{+ 1 \text{/} 2} + {f}_{h}^{- 1 \text{/} 2}} = \frac{Δ {f}_{h}}{{f}_{h}} \qquad ( 17 )$$

where ƒ_{e,h}=ƒ_{e,h}^{+1/2}+ƒ_{e,h}^{-1/2} is the total of electron or hole population. This equation shows that J-polarization is directly proportional to spin-polarization.

### Time-Resolved Faraday Rotation (TRFR) Experimental Setup

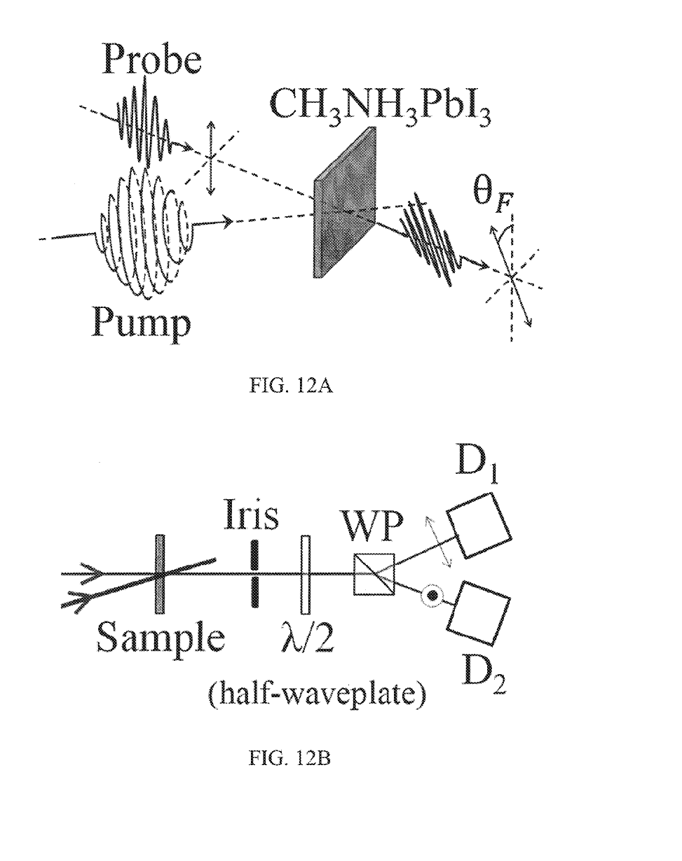

The setup for TRFR is similar as the setup shown in FIG. 11A, except for the replacement of the quarter-wave plate before detection with a half-wave plate (FIG. 12B). The rotation of the probe polarization was calculated from:

$${θ}_{F} = \frac{Δ I}{2 {I}_{0}} \qquad ( 18 )$$

where ΔI=Iₚ−Iₛ is pump-induced difference between transmitted p-polarized and s-polarized component, I₀=Iₚ+Iₛ is the total probe intensity and θ_{F} is the Faraday angle in radians, which is proportional to sample magnetization, i.e., Eq. (11) (polarization of carrier angular momentum).

From Eq. (11) it can be seen also that the lifetime of Faraday rotation signal is half of the J-flip lifetime (τₛ) due to the factor of 2 in the rate of exponential decay. It is noted that the system must be balanced (i.e., Iₛ=Iₚ) by adjusting the half-wave plate prior to the introduction of any pump excitation to correct for any non-pump induced Faraday rotation artifacts. When pump is introduced, probe rotation will change the balance between Iₛ and Iₚ which therefore give rise to the pump-induced Faraday rotation signal. It is also noted that this detection is neither sensitive to the change of I₀ nor probe ellipticity, but only to probe rotation. No Faraday rotation signal was observed from a blank quartz substrate.

### Example 2

### Room Temperature Spin-Selective Optical Stark Effect In Layered Halide Perovskites

Ultrafast spin manipulation for opto-spin logic applications require material systems possessing strong spin-selective light-matter interaction. Conventional inorganic semiconductor nanostructures (e.g., epitaxial II-VI quantum-dots and III-V multiple quantum-wells (MQWs)) are considered forerunners but encounter challenges of lattice-matching and cryogenic cooling requirements. Two-dimensional (2D) halide perovskite semiconductors, combining intrinsic tunable MQWs structures and large oscillator strengths with facile solution-processability, can offer breakthroughs in this area. In this example it is demonstrated novel room-temperature, strong ultrafast spin-selective optical Stark effect (OSE) in solution-processed (C₆H₄FC₂H₄NH₃)₂PbI₄ perovskite thin films. Exciton spin states are selectively tuned by ˜6.3 meV using circularly-polarized optical pulses without any external photonic cavity (i.e., corresponding to a Rabi-splitting ˜55 meV and equivalent to applying a 70 T magnetic field)—much larger than any conventional system. Importantly, the facile halide and organic replacement in these perovskites affords control of the dielectric confinement and hence presents a straight-forward strategy for the tuning the light-matter coupling strength.

OSE is a coherent, non-linear light-matter interaction arising from the hybridization between photons and electronic states (also known as the photon-dressed state). Spin-selective OSE with the additional spin degree of freedom, offers exciting new prospects for realizing opto-spin-logic and Floquet topological phases for ultrafast optical implementations of quantum information applications. Apart from the fundamental criterion of large oscillator strengths for effective mode splitting, spin-switching applications utilizing OSE also imposes additional material selection demands requiring: (a) strong spin-orbit coupling (SOC) for spin selectivity; (b) high charge mobility for electronic integration and (c) room-temperature operation for practical applications. Material systems that could simultaneously fulfil all these requirements are far and few between. Substrate-insensitive organics (e.g., J-aggregates) would be excluded due to (a). Conventional III-V or II-VI inorganic nanostructures grown under stringent lattice-matched conditions while fulfilling (a) and (b) are severely limited to cryogenic temperature operations for clear resolution of the spin-states. Tuning the Rabi-splitting in these conventional systems without the aid of external photonic cavities is an extremely arduous endeavour. The 2D organic-inorganic halide perovskites family of materials can fulfil all the above demands whilst offering facile tunability and strong spin-selectivity.

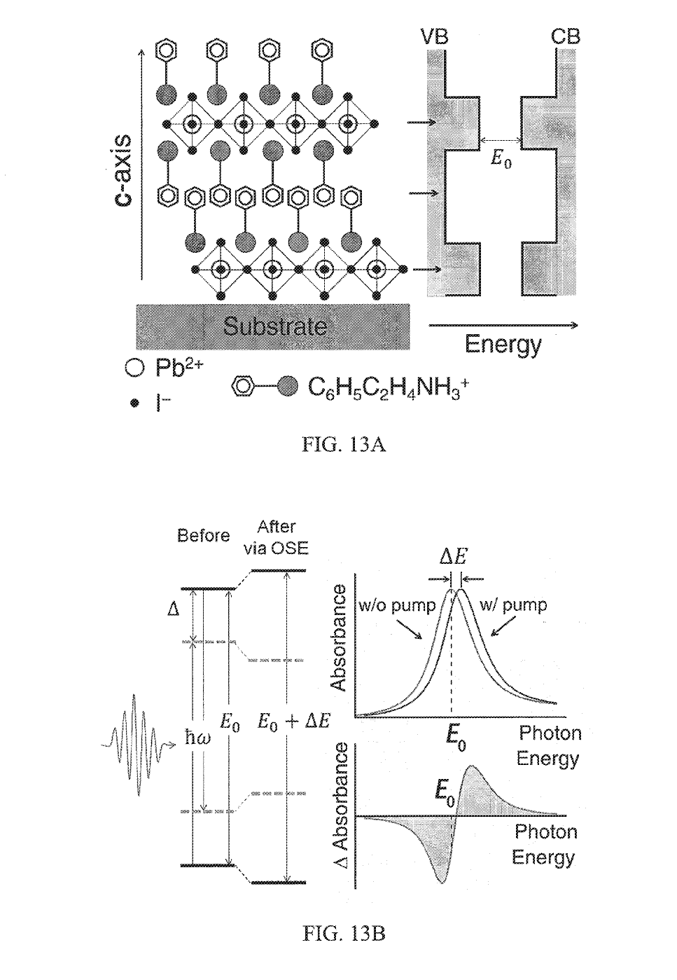

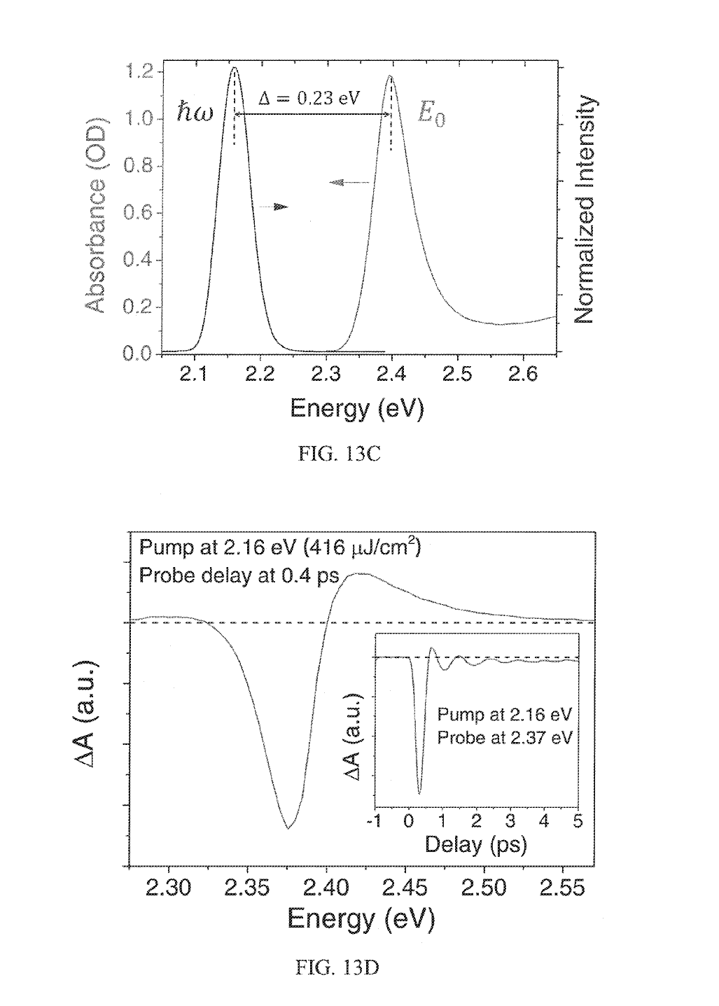

In this example, the inventors attempt to tackle such issues through organic-inorganic halide perovskites (OIHP) material system. Recently, halide perovskites (e.g., CH₃NH₃PbI₃) with outstanding optoelectronic properties, are in the limelight due to their record solar cell efficiencies exceeding 20%. CH₃NH₃PbI₃ is a three-dimensional (3D) analogue belonging to the broad halide perovskite family, which is characterized by their large spin-orbit coupling (SOC) originating from the heavy Pb and I atoms in their structure. Indeed, novel spin and magnetic field phenomena in CH₃NH₃PbI₃ have recently been discovered, highlighting their potential for spin-based applications. Unlike 3D perovskites where the organic and inorganic constituents are uniformly distributed, the 2D analogue, e.g., (C₆H₅C₂H₄NH₃)₂PbI₄—hereafter is simply termed PEPI, comprises of alternating organic (C₆H₅C₂H₄NH₃⁺) and inorganic ([PbI₆]⁴⁻ octahedron) layers forming naturally self-assembled MQWs structures—FIG. 13A. These repeating organic and inorganic layers bound together by van der Waals interaction form the barrier and the well, respectively. Likewise, 2D perovskites also possesses outstanding optoelectronic properties and relatively high in-plane carrier mobilities (˜2.6 cm² V⁻¹ s⁻¹), based on which transistors and light-emitting devices have previously been demonstrated. The large dielectric contrast between the barrier and the well gives rise to strong dielectric confinement which enhances its exciton binding energy (hundreds of meV) and oscillator strength. These unique properties of 2D perovskites point to a highly promising system for realizing intrinsic spin-selective OSE, even in the absence of any photonic cavity.

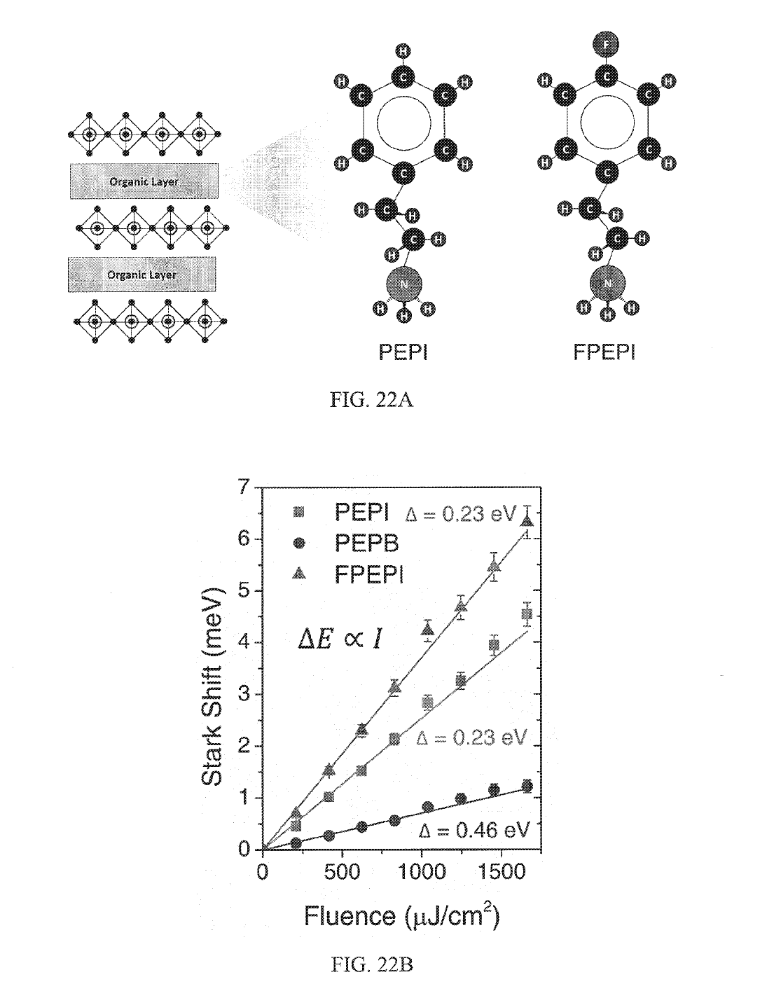

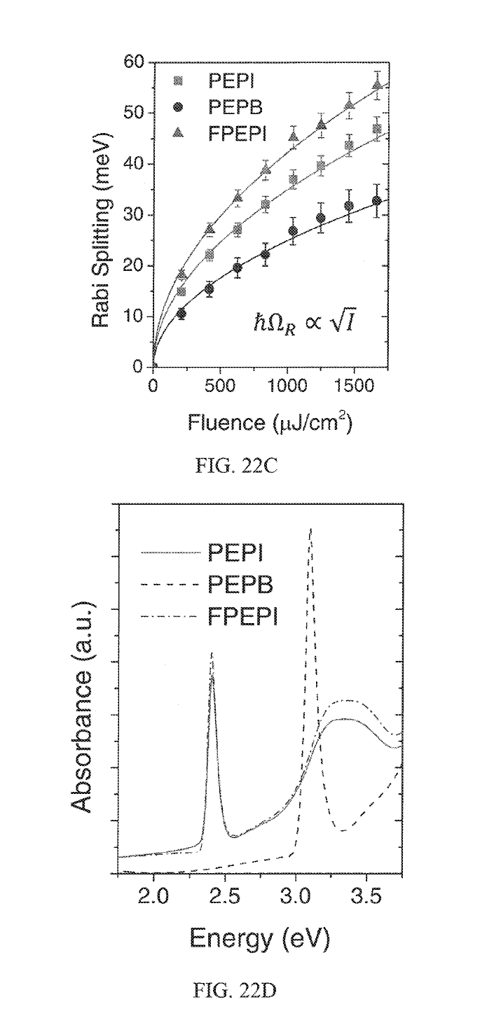

FIG. 13B shows the key spectral signatures of OSE: (i) non-resonant photoexcitation induced transient blue shift ΔE of the excitonic absorption peak E₀ (e.g., with photon energy ω<E₀ that is detuned by Δ) and (ii) a derivative-like feature in the differential absorption spectrum as a result of the transient shift of the energy levels. This phenomenon could also be understood from the Floquet picture as a repulsion between the equilibrium states and Floquet quasi-states—FIG. 13B and later paragraphs for detailed discussion. FIG. 13C shows the excitonic absorption peak of PEPI at E₀ ˜2.39 eV and the pump pulse of ˜2.16 eV (i.e., detuned by Δ≈0.23 eV) as the excitation source. FIG. 13D shows the characteristic OSE spectral signature in the transient absorption (TA) spectrum of the PEPI film (at 0.4 ps probe delay) following a linearly polarized pump and probe photoexcitation at 2.16 eV with a fluence of 416 μJ/cm². Here, the derivative-like feature in the TA spectrum comprises of the OSE signal (FIG. 13B) superimposed on a photobleaching (PB) peak (i.e., negative AA peak) arising from the state-filling of excitons from two-photon excitation (see later discussion). The kinetic trace at 2.37 eV probe (FIG. 13D inset) shows that the ultrafast OSE process is comparable to the pulse duration. The much weaker oscillatory PB signal arises from coherent exciton dynamics (see FIG. 24). The inventors next proceed to separate these contributions using circularly-polarized pump-probe measurements and demonstrate that the degeneracy between spin up and down states can be selectively lifted by as much as 6.3±0.3 meV for fluorinated-PEPI (hereafter termed FPEPI—see FIG. 22A-D) or 4.5±0.2 meV for PEPI at room temperature without any cavity nor any externally applied B-field. Equivalently, this magnitude of energy separation through the Zeeman effect will require an applied B-field >70 T for FPEPI (or >50 T for PEPI)—see later paragraph.

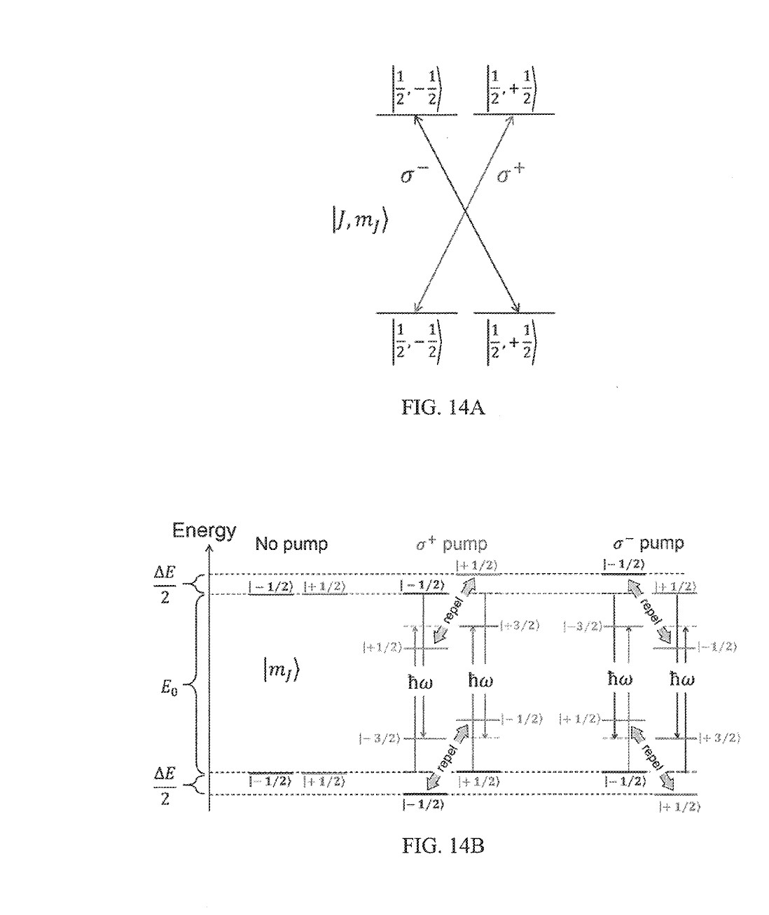

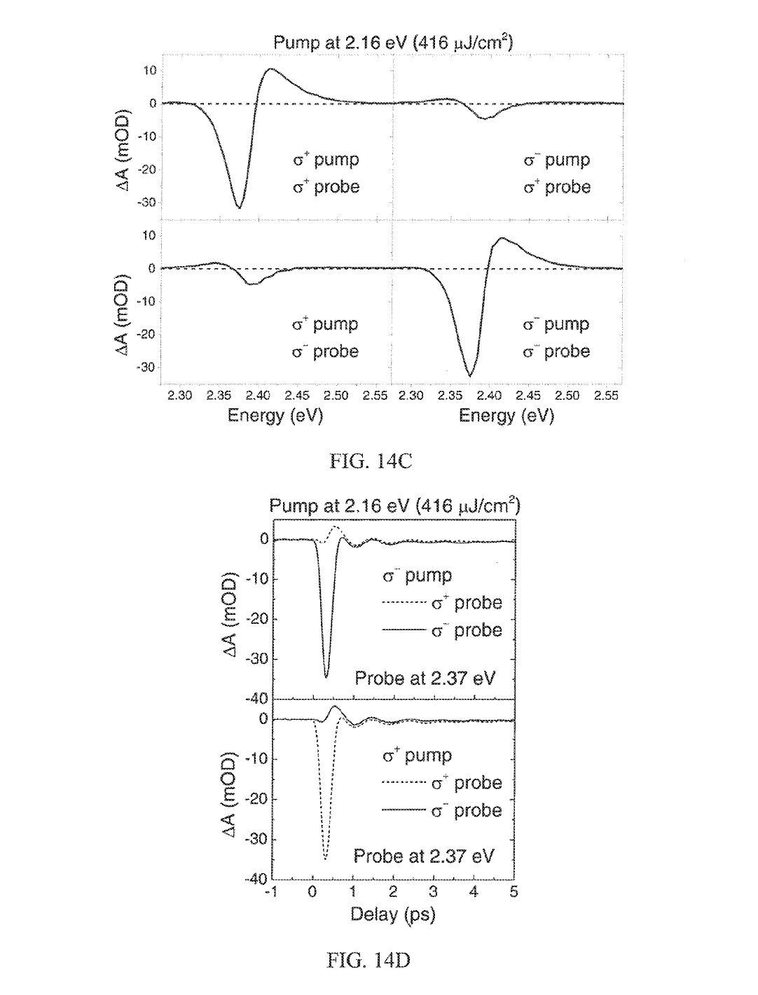

The origins and the mechanism of the spin selectivity are first examined and the spin selection rules for OSE in PEPI are established. In this 2D halide perovskite system, the conduction band (CB), which is strongly affected by the crystal field and large SOC, arises mainly from the Pb 6p orbital; while the valence band (VB), which is unaffected by them, arises mainly from the Pb 6s orbital. It is well-established that the organic component does not play any significant role in determining the electronic structure. Taking into account the crystal field and SOC, the electronic structures of both the VB maximum and CB minimum are described by the angular momentum quantum number J=½, and magnetic quantum number m_{J}=±½, which is preserved for the case of excitons. FIG. 14A shows the optical selection rules for the photon with wavevector k parallel to the c-axis (i.e., k//c or k perpendicular to the substrate). Conservation of angular momentum dictates that the absorption of left circularly (σ⁺) and right circularly (σ⁻) polarized light will raise and lower m_{J} by 1, respectively. Similar to earlier example for the 3D CH₃NH₃PbI₃, absorption of circularly polarized light will create J-polarized (or spin-polarized) species, which in this case is spin-polarized excitons.

Based on these selection rules, FIG. 14B illustrates the spin-selective OSE mechanism in PEPI. From the quantum mechanical description (see below), only the Floquet quasi-states with the same m_{J} as the equilibrium states will undergo a repulsion (i.e., for |m_{J}=—½ [symbol] but not for |m_{J}=± 3/2 [symbol] —FIG. 14B) in the presence of the σ^{±} pump. This gives rise to the spin-selective OSE, whose coupling strength is parameterized by the Rabi splitting. FIG. 14C shows the co- and counter-circular pump and probe TA spectra. The corresponding kinetic traces of the probe at the negative AA peak (˜2.37 eV) are given in FIG. 14D. The circularly-polarized probe is sensitive to the occupancy of exciton spin-states. The figures show a large photoinduced signal (i.e., −ΔA arising from OSE and state-filling) when both the pump and the probe beams are co-circular. The signal is greatly reduced for the counter-circular case. The large −ΔA signal present only when both the pump and probe beams have the same helicity indicates a highly occupied spin-state with a specific spin orientation. This validates the spin-selectivity of the OSE signal in PEPI. The small −ΔA signal present in the counter-circular pump and probe spectra arises from the state-filling due to two-photon photoexcitation which will be discussed later.

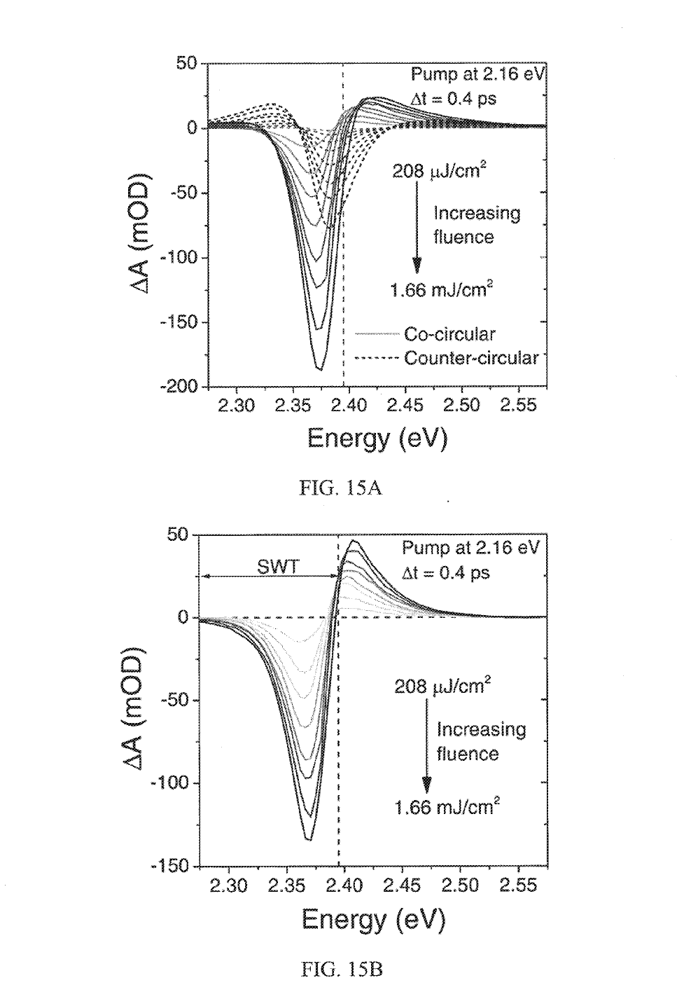

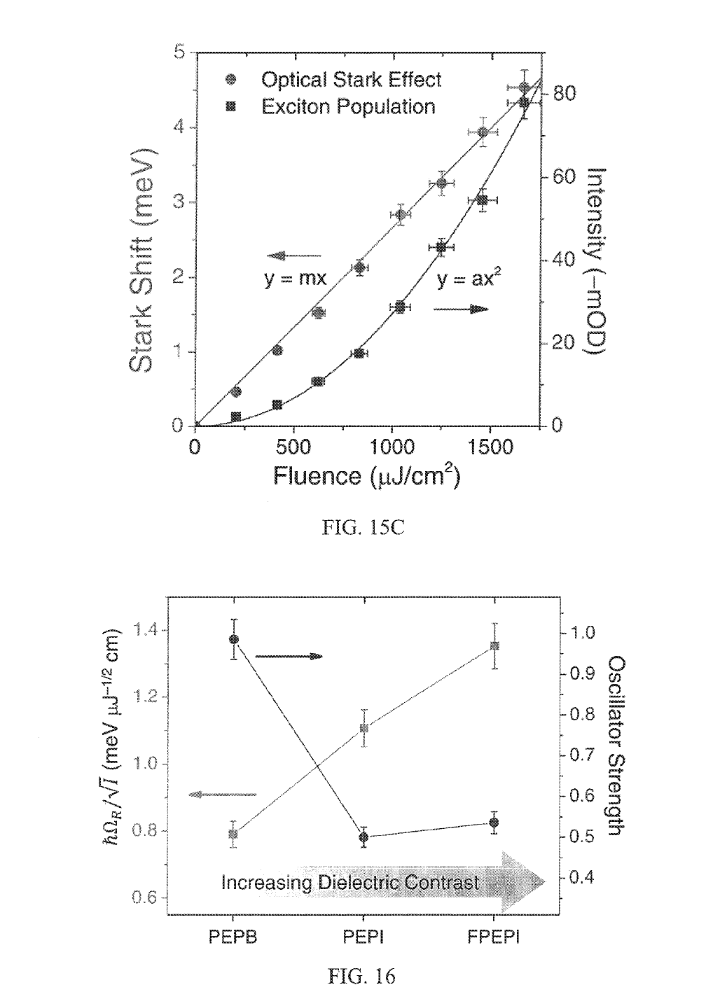

FIG. 15A shows the fluence dependent TA spectra for both co- and counter-circular pump and probe configurations from 0.208 mJ/cm² to 1.66 mJ/cm². The spectral signature increases with increasing pump fluence for both configurations, but is much larger for the co-circular case. Based on the excitonic peak in the linear absorption spectrum (FIG. 13C), the inventors attribute the −ΔA peak (2.39 eV) in the counter-circular TA spectrum to arise from the state-filling of the excitons. This exciton bleaching signal exhibits a pump-dependent quadratic behaviour consistent for a two-photon excitation process—FIG. 15C. To elucidate the OSE contribution and eliminate the excitonic contribution from the signal, the inventors subtract the co-circular TA signal from the counter-circular TA signal at the same pump fluence FIG. 15B. The inventors estimate the energy shift ΔE from the OSE using the spectral weight transfer (SWT) of the OSE signal—see below. FIG. 15C shows the linear dependence of the OSE on the pump fluence, which yields excellent agreement with the predictions from theory—Eq. (19).

$$Δ E = \sqrt{{ℏ}^{2} {Ω}_{R}^{2} + {Δ}^{2}} - Δ \approx \frac{{( ℏ {Ω}_{R} )}^{2}}{2 Δ} ∝ Intensity \qquad ( 19 )$$

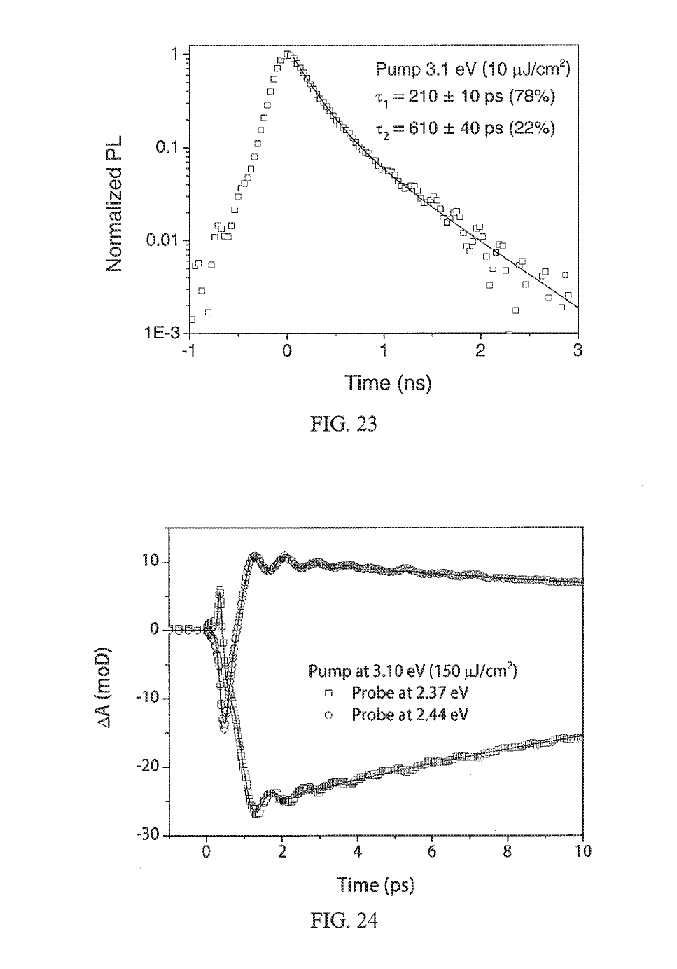

In Eq. (19), Ω_{R} is the Rabi splitting and Δ is the detuning energy. The approximation holds for the case of Δ>>Ω_{R}. A large ΔE of 4.5±0.2 meV at room temperature can be tuned with a pump fluence of 1.66 mJ/cm² without any external magnetic field—FIG. 15C. At a given fluence of 1.66 mJ/cm², Δ=0.23 eV and ΔE=4.5±0.2 meV, the corresponding Ω_{R}=47±2 meV—calculated by using Eq. (19). From this result, the inventors determine the exciton reduced mass and the transition dipole moment (TDM) to be (0.11±0.01)m₀ and (5.26±0.20)×10⁻²⁹ Cm, respectively, where me is the free electron rest mass—see below for details. This result is consistent with previous reports and thus confirms the accuracy of the present measurement. Furthermore, as self-consistency check, from the TDM value the inventors determine radiative lifetime to be 95±6 ps, which correspond well with the experimental data (FIG. 23), thereby further validating the measurements. Comparatively, in systems without any external photonic cavity, this room-temperature Ω_{R} value is larger than that for Mn-doped CdTe QD (at 5 K); or approximately 4 times larger than the largest value reported for GaAs/AlGaAs QWs (at 15 K) photoexcited by fs pump with similar fluence—see Table 1. Although a recent publication on valley-selective OSE in monolayer WS₂ reported 18 meV energy splitting, these 2D transition-metal dichalcogenides face stringent monolayer constraints which is essential for valley-selectivity and also suffer from lower carrier mobility (˜0.23 cm²V⁻¹s⁻¹).

Tuning the coupling strength or Rabi-splitting in 2D perovskite is not as trivial as merely modulating the exciton oscillator strength of the material. While a large oscillator strength is important for obtaining a large Rabi splitting, other contributions such as the effective mass and band gap also play crucial roles (Eq. (49)). A more deterministic criterion is the dielectric contrast between the barrier and the well layer. FIG. 16 shows a plot of Rabi splitting per square-root of fluence (ÅΩ_{R}/\sqrt{I}) for various solution-processed 2D perovskite systems as function of oscillator strength and the dielectric contrast. The dielectric constant of the barrier layer can be further reduced by fluorination of the organic layer (i.e. C₆H₅C₂H₄NH₃⁺ to C₆H₄FC₂H₄NH₃⁺, hence PEPI to FPEPI—see FIG. 22A-D) due to the increase in free volume fraction and large electronegativity of C—F bond, thus enhancing the dielectric contrast. Such simple substitution of organic component enhances ΔE from 4.5±0.2 meV (i.e., Ω_{R}=47±2 meV) to 6.3±0.3 meV (i.e., Ω_{R}=55±3 meV)—see FIG. 22A-D.

Meanwhile, the dielectric constant of the well layer can be reduced by substituting the halide component from iodide (˜6.1) to bromide (˜4.8), thus reducing the dielectric contrast. The inventors demonstrate that while ÅΩ_{R}/\sqrt{I} does not exhibit any clear trend with the oscillator strength, there is direct increasing correspondence with the dielectric contrast. This later parameter would therefore provide a clear criterion for the straight-forward tuning of the coupling strength in 2D perovskite.

In summary, the present findings show that the facile solution-processed natural MQWs 2D perovskite possess highly desirable characteristics for ultrafast spin-selective OSE. The PbI₆ layer lends inorganic character to 2D perovskites while the organic constituent bestows their solution processability. Their low-temperature solution processing is highly amendable for a broad range of substrates. In the absence of any external photonic cavity or hybrid metal-nanostructures, OSE-induced ultrafast optical spin-selective energy level splitting of ΔE=4.5±0.2 meV (ΔE=6.3±0.3 meV) and corresponding Rabi-splitting Ω_{R}=47±2 meV (Ω_{R}=55±3 meV) at room temperature is demonstrated in PEPI (FPEPI). In principle, a larger energy shift ΔE is possible if the pump pulse with a smaller detuning Δ is used (e.g., with a picosecond laser). Here, the inventors are limited by the spectral bandwidth of the inventors' femtosecond laser system with FWHM ˜30 nm. Tuning of the energy level splitting and Rabi-splitting and are also feasible through halide or organic cation replacement (dielectric contrast tuning) and with the use of optical microcavities. A high quality external photonic microcavity will greatly enhance the strength of light-matter interaction through strong photon modal confinement (Eq. (27)), where Rabi splitting ˜190 meV from PEPI under lamp excitation was previously demonstrated. This present work aptly demonstrates the untapped potential of halide perovskites for new applications beyond photovoltaics and light emission. The facile processability of these systems together with the strategy of tuning the dielectric contrast, this family of materials would open up new avenues for ultrafast opto-spin-logic applications.

### Sample Preparation

All the chemicals were purchased from Sigma-Aldrich. C₆H₅C₂H₄NH₃I was prepared by adding 5.45 ml of HI (57%) to the mixer of 5 g of C₆H₅C₂H₄NH₃ and 5 ml of methanol at 0° C. The reaction mixture was further stirred for an hour at room temperature. Excess solvent was then removed using the rotary evaporator at 50° C. to obtain a white powdery mass. The powder was then washed with cold ether for several times and dried to obtained C₆H₅C₂H₄NH₃I powder. (C₆H₅C₂H₄NH₃)₂PbI₄ solution was subsequently obtained by dissolving stoichiometric amounts (2:1) of C₆H₅C₂H₄NH₃I and PbI₂ in N,N-dimethylformamide. The weight concentration of this solution was fixed at 12.5 wt %. The sample was fabricated by spincoating the solution on a cleaned quartz substrate at 4000 rpm and 30 s. The (C₆H₅C₂H₄NH₃)₂PbI₄ (PEPI) film (45±5 nm-thick) was subsequently annealed at 100° C. for 30 minutes. Other thin films samples were prepared by similar methods with their respective component and stoichiometric ratio.

### Experimental Setup

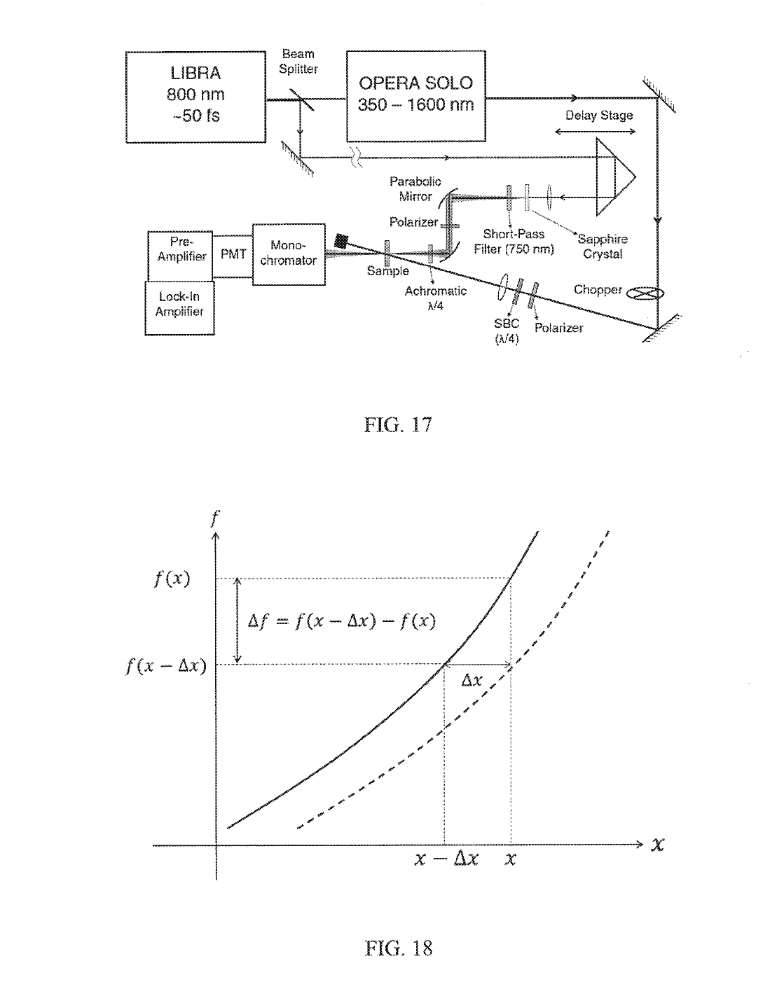

The laser system used is the Coherent Inc. Libra™ Ti:Sapphire laser with ˜50 fs pulse width at a 1 kHz repetition rate. The output was split into two beams. One beam was directed to the optical parametric amplifier (Coherent OPeRa SOLO™) to generate tunable photon energy for the pump. The weaker beam was steered to a delay stage, before being focused to a sapphire crystal for white light generation (1.4 eV-2.8 eV), which used as the probe. The transient absorption was performed using the inventors' home-build transient absorption setup as shown in FIG. 17. The measurement was performed in transmission mode. Transmitted probe was collected and sent to monochromator and photo multiplier tube (PMT) with lock-in detection (at a chopper frequency of 83 Hz). Linear polarizers were used for both the linearly polarized pump and probe measurements. A Solei Babinet Compensator (SBC) and an achromatic quarter wave plate (λ/4) were used to generate circular polarization for the pump and probe beams, respectively for the circularly pump and probe measurements. Intensity control in this experiment was performed by using variable density filters. Chirp-correction in the TA spectra was also implemented.

### Estimation of Energy Shift ΔE

For a given spectrum described by function ƒ(x), it can be calculated the transient change of the spectrum due to a positive shift of Δx. The transient change Δƒ, as illustrated by FIG. 18, can be described as:

$$Δ f ( x ) = f ( x - Δ x ) - f ( x ) \approx - \frac{d f ( x )}{d x} Δ x \qquad ( 20 )$$

which is proportional to the first derivative of the function. For a known ƒ(x), the first derivative can be analytically solved and used to fit the experimental data to estimate Δx. Nevertheless, for a general case of an unknown peak function ƒ(x), another approach to estimate Δx would be through what is defined as spectral weight transfer (SWT):

$$SWT = {{\int }_{0}}^{{x}_{0}} Δ f ( x ) d x \qquad ( 21 )$$

where x₀ is the peak position. SWT can be easily calculated numerically from the present experimental data, without knowing the analytical function.

By the first fundamental theorem of calculus, Eq. (20) substituted to Eq. (21), can be simplified into:

$$SWT = - Δ x {{\int }_{0}}^{{x}_{0}} \frac{d f ( x )}{d x} d x = - Δ x ( f ( {x}_{0} ) - f ( 0 ) ) \qquad ( 22 )$$

For the present case, ƒ(x) is A(E), where A(E) is the absorbance of the material as a function of photon energy E. Since A(0)=0, the energy shift ΔE due to the optical Stark effect (with E₀ is the peak absorption energy) in the present experiment can be estimated as:

$$Δ E = - \frac{SWT}{A ( {E}_{0} )} = - \frac{1}{A ( {E}_{0} )} {{\int }_{0}}^{{E}_{0}} Δ A ( E ) d E \qquad ( 23 )$$

Here, A(E₀)=1.186 OD at E₀=2.39 eV which is the peak absorbance (FIG. 13C). As the OSE signal vanishes below 2.25 eV, the integration limits are set within range 2.25 eV≦E≦2.39 eV.

### Quantum Mechanical Description of the Optical Stark Effect (OSE)

The inventors start by applying the Jaynes-Cummings model of interaction in a system with two optically coupled eigenstates |1 [symbol] and |2 [symbol] with energy E₁ and E₂, respectively, i.e., E₂−E₁=ω₀>0, in the presence of electromagnetic radiation with photon energy ω. The total Hamiltonian of the system comprises of three distinct components:

H_{S}=E₁|1 [symbol] [symbol] 1|+E₂|2 [symbol] [symbol] 2| (24)

H_{L}=Åω(â^{†}â+½) (25)

H_{I}=Åω_{R}(|1 [symbol] [symbol] 2|â^{†}+|2 [symbol] [symbol] 1|â) (26)

where H_{S}, H_{L} and H_{I} are the Hamiltonian of the two-level system, the electromagnetic (EM) radiation, and the interaction between them, respectively. The Rabi frequency is given by Ω_{R}=2ω_{R}\sqrt{(n+1)}, where ω_{R} is the vacuum Rabi frequency and n is the numbcr of photons in the system.

The vacuum Rabi frequency ω_{R} is given by:

$${ω}_{R} = \vert {p}_{12} \vert \sqrt{\frac{ℏ ω}{2 ò {V}_{m}}} \qquad ( 27 )$$

The |p₁₂|= [symbol] 1|p|2) is the transition dipole moment which contains the optical selection rule for transition, where p is the electric dipole operator, c is the dielectric constant and Vₘ is the photon confinement (cavity mode) volume. The inverse relation between the Rabi frequency to the square root of the photon confinement volume allows for addition degree of freedom to tune Ω_{R} using different cavities. In the present case, no external photonic cavity is used in the present spin-coated thin films.

Here, Ω_{R} parameterizes the coupling strength between the system and the EM radiation. The operators â^{†} and â are the creation and annihilation operators of the photon, respectively, which act on the Fock states |n [symbol] as follows:

â^{†}|n [symbol] =\sqrt{n+1}|n+1 [symbol] (28)

â|n [symbol] =\sqrt{n}|n−1 [symbol] (29)

The total Hamiltonian of the system is given by the summation of H_{S}, H_{L} and H_{I}. Here, the two states that are of interest are: |1,n+1 [symbol] and |2,n [symbol] . Using these two states {|1,n+1 [symbol] , |2,n [symbol] } as the basis, the total Hamiltonian can be written in matrix representation as:

$$H = ( \begin{matrix}{E}_{1} + ℏ ω ( n + \frac{3}{2} ) & \frac{1}{2} ℏ {Ω}_{R} \\ \frac{1}{2} ℏ {Ω}_{R} & {E}_{2} + ℏ ω ( n + \frac{1}{2} )\end{matrix} ) \qquad ( 30 )$$

Without the loss of generality, the energy level reference can be set such that E₁=−ω₀/2 and E₂=ω₀/2. The Hamiltonian can therefore be rewritten as:

$$\begin{matrix}H = ( \begin{matrix}- \frac{ℏ {ω}_{0}}{2} + ℏ ω ( n + \frac{3}{2} ) & \frac{1}{2} ℏ {Ω}_{R} \\ \frac{1}{2} ℏ {Ω}_{R} & \frac{ℏ {ω}_{0}}{2} + ℏ ω ( n + \frac{1}{2} )\end{matrix} ) \\ = ( \begin{matrix}- \frac{Δ}{2} + ℏ ω ( n + 1 ) & \frac{1}{2} ℏ {Ω}_{R} \\ \frac{1}{2} ℏ {Ω}_{R} & \frac{Δ}{2} + ℏ ω ( n + 1 )\end{matrix} )\end{matrix} \qquad ( 31 )$$

where Δ=ω₀−ω is the detuning energy between the equilibrium state and the photon energy of the laser. If the two-states are not optically coupled, i.e., Ω_{R}=0, the Hamiltonian will reduce to:

$$H = ( \begin{matrix}- \frac{Δ}{2} + ℏ ω ( n + 1 ) & 0 \\ 0 & \frac{Δ}{2} + ℏ ω ( n + 1 )\end{matrix} ) \qquad ( 32 )$$

In this case for the Hamiltonian without light-matter interaction in Eq. (32), the eigenstates of [symbol] |1,n+1 [symbol] and |2, n [symbol] are called bare states.

In the presence of light-matter interaction, Ω_{R}>0. |1,n+1 [symbol] and |2,n [symbol] are no longer the eigenstates of the system, as the Hamiltonian is not diagonal. The new eigenstates can be obtained by diagonalizing the Hamiltonian in Eq. (31):

$$H = ℏ ω ( n + 1 ) ( \begin{matrix}1 & 0 \\ 0 & 1\end{matrix} ) + ( \begin{matrix}- \frac{1}{2} \sqrt{{( ℏ {Ω}_{R} )}^{2} + {Δ}^{2}} & 0 \\ 0 & \frac{1}{2} \sqrt{{( ℏ {Ω}_{R} )}^{2} + {Δ}^{2}}\end{matrix} ) \qquad ( 33 )$$

with two new eigenstates |n− [symbol] and |n+ [symbol] as the new basis of the diagonalized Hamiltonian. The constant energy shift of ω(n+1) in the eigenenergies is due to the presence of other photons in the system. Here, \sqrt{(ÅΩ_{R})²+Δ²}/Å is also called as generalized Rabi frequency. The relation between the new basis set and the previous basis set are given by:

$$\begin{matrix}\vert n - 〉 = - sin {θ}_{n} \vert 1 , n + 1 〉 + cos {θ}_{n} \vert 2 , n 〉 & ( 34 ) \\ \vert n + 〉 = cos {θ}_{n} \vert 1 , n + 1 〉 + sin {θ}_{n} \vert 2 , n 〉 & ( 35 ) \\ cos {θ}_{n} = \frac{\sqrt{{( ℏ {Ω}_{R} )}^{2} + {Δ}^{2}} - Δ}{\sqrt{{( \sqrt{{( ℏ {Ω}_{R} )}^{2} + {Δ}^{2}} - Δ )}^{2} + {( ℏ {Ω}_{R} )}^{2}}} & ( 36 ) \\ sin {θ}_{n} = \frac{ℏ {Ω}_{R}}{\sqrt{{( \sqrt{{( ℏ {Ω}_{R} )}^{2} + {Δ}^{2}} - Δ )}^{2} + {( ℏ {Ω}_{R} )}^{2}}} . & ( 37 )\end{matrix}$$

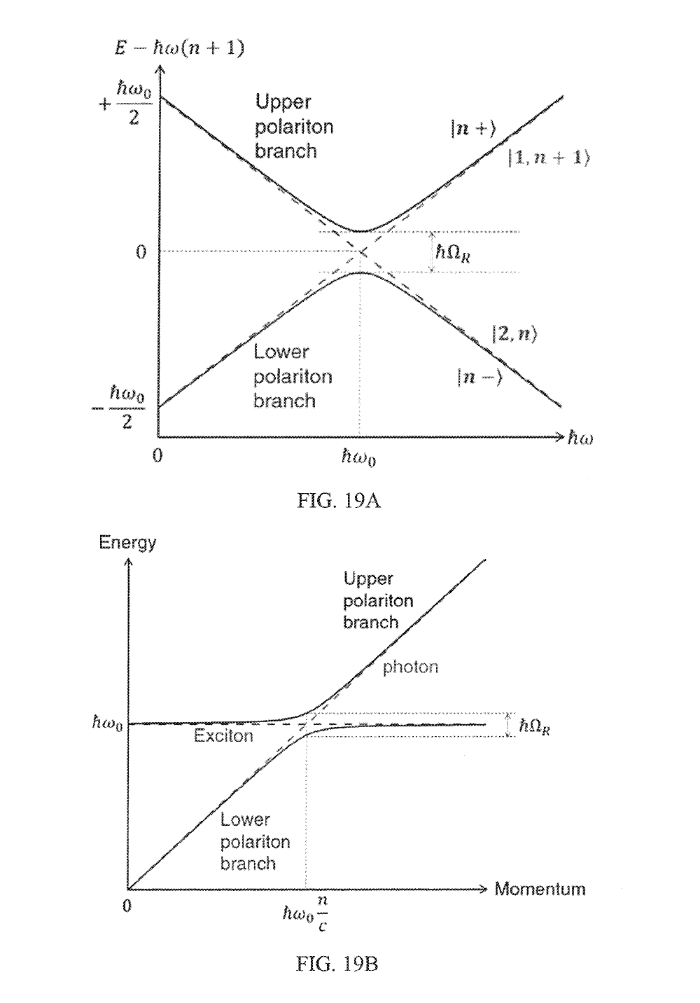

These two new eigenstates are also known as the Floquet states or dressed states, which also known as exciton-polariton states in the case for semiconductors. A plot of the eigenenergies as function of ω for the case of with (solid lines) and without light-matter interaction (dashed lines) is given in FIG. 19A. As expected, the two eigenenergies of the bare states are degenerate for the case of resonant photon energy (Δ=0); the energy of n photon with the system in the excited state |2 [symbol] is equal to energy of n+1 photon with the system in the ground state |1 [symbol] . An important phenomenon shown in the figure is that the energy gap between the two new eigenstates |n+ [symbol] and |n− [symbol] (upper and lower polariton branch, respectively) is increased by the interaction with the photon, as compared to the gap between the bare states (|2, n [symbol] , |1, n+1 [symbol] ). This is known as the AC Stark effect or Optical Stark Effect (OSE). OSE causes the absorption spectrum of the system to shift by ΔE, which is related to the Rabi splitting (Ω_{R}) and detuning energy Δ as:

$$Δ E = \sqrt{{( ℏ {Ω}_{R} )}^{2} + {Δ}^{2}} - Δ \approx \frac{{( ℏ {Ω}_{R} )}^{2}}{2 Δ} ∝ Intensity . \qquad ( 38 )$$

The approximation is valid for the case of Δ>>Ω_{R}. Since Ω_{R} is proportional to the electric field induced by light, the Stark shift is therefore expected to be linear to the pump fluence.

FIG. 19B plots the dispersion relation (energy vs momentum) of the dressed states (solid lines) and the bare states (dashed lines), for the case of the exciton in a semiconductor. The dispersion relation of a bare exciton E_{X} and a bare photon Eₚₕ are given by:

$$\begin{matrix}{E}_{X} = ℏ {ω}_{0} + \frac{{p}^{2}}{2 M} & ( 39 ) \\ {E}_{ph} = \frac{c}{n} p & ( 40 )\end{matrix}$$

where p is the momentum, M is the exciton mass and n is the refractive index. It is noted that this equation applies in the approximation of ω₀>>p²/2M, such that the resonance (Δ=0) occurs at Eₚₕ≈ω₀. The dispersion relation of the polariton, which is a photon-dressed state of exciton (or a quasi-particle hybrid of the photon and exciton), is therefore given by:

$$\begin{matrix}E = \frac{{E}_{X} + {E}_{ph}}{2} \pm \frac{1}{2} \sqrt{{( ℏ {Ω}_{R} )}^{2} + {Δ}^{2}} \\ = \frac{1}{2} ( ℏ {ω}_{0} + \frac{{p}^{2}}{2 M} + \frac{c}{n} p ) \pm \frac{1}{2} \sqrt{{( ℏ {Ω}_{R} )}^{2} + {( ℏ {ω}_{0} - \frac{c}{n} p )}^{2}}\end{matrix} \qquad ( 41 )$$

The + and − signs are for upper and lower polariton branches, respectively. It is clear from such relation that when there is no interaction (i.e., ω_{R}=0), the energy dispersion will reduce to either the bare exciton or bare photon case with a crossing between them at resonance. The gap of the anti-crossing for the case of Ω_{R}>0 at resonance is called the Rabi splitting.

### Estimation of the Rabi Splitting

From Eq. (37) and the present experimental values for Δ=0.23 eV and ΔE=4.5 meV, the inventors estimate the Rabi splitting of the present PEPI thin film system at the fluence of 1.66 mJ/cm²: Ω_{R}≈47 meV.

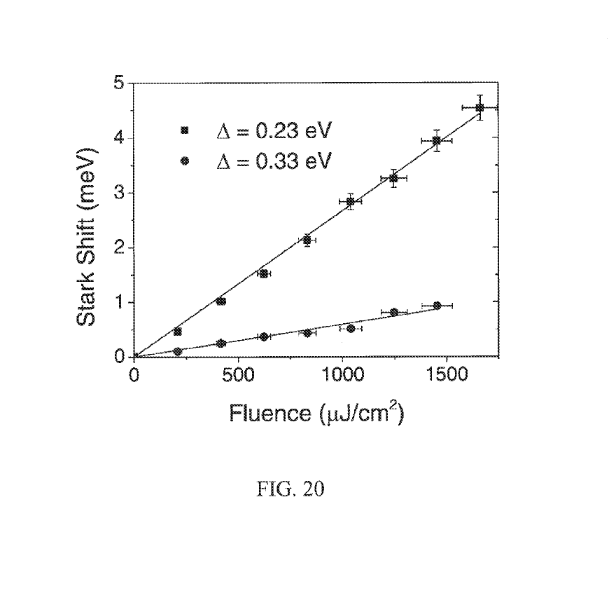

As a self-consistency check on the model, the inventors also repeated the experiments with a different detuning energy Δ=0.33 eV. The results are plotted in FIG. 20, which also show a linear relationship. Since Ω_{R} is proportional to the electric field of the light, i.e., the square root of the number of photons or the square root of the intensity (fluence divided by pulse width), the inventors estimate the Ω_{R} for the case Δ=0.33 eV at a fluence 1.46 mJ/cm² to be:

$$ℏ {Ω}_{R} \approx 47 meV \times \sqrt{\frac{1.46 mJ \text{/} {cm}^{2}}{1.66 mJ \text{/} {cm}^{2}} \times \frac{290 fs}{680 fs}} \approx 29 meV \qquad ( 42 )$$

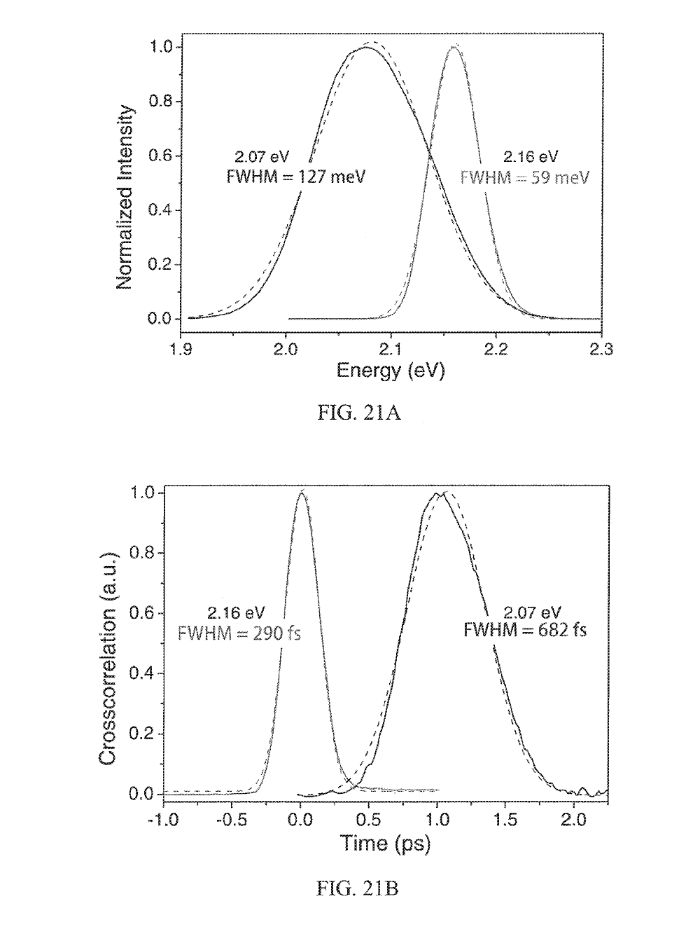

Here, the inventors also have to take into account the effect of the difference in the pump pulse durations, which was obtained from the pump-probe cross correlation in the present setup—see FIG. 21B. Using this value of Rabi frequency Ω_{R}=29 meV, the OSE energy shift at Δ=0.33 eV and fluence 1.46 mJ/cm², the energy shift ΔE can be estimated to be ΔE≈21.2 meV, which is consistent with the presently obtained experimental value of 0.92 meV, as shown in FIG. 20.

### Comparison of Rabi Splitting

Comparison of energy shift by OSE and the value of Rabi splitting for various inorganic semiconductors is presented in Table 1 below, together with the laser system and intensity reported to reach such splitting. A fair comparison can only be made on GaAs/AlGaAs quantum well, due to similar femtosecond laser system and pump intensity; in which PEPI thin films prevails by ˜4 times higher magnitude of Rabi splitting. Moreover, such value is reached in room temperature, as contrast to cryogenic temperature typically used for study in inorganic semiconductor nanostructures.

TABLE 1
Comparison of OSE and Rabi splitting in various inorganic semiconductor.

| | Pump Intensity | | Δ | ΔE | Ω_{R}^{†} |
|---|---|---|---|---|---|
| Material | (Laser System) | T (K) | (meV) | (meV) | (meV) |
| PEPI thin film (Present result) | 5.5 GW/cm² | 300 | 230 | 4.5 | 47 |
| Single Mn-doped CdTe QD (10- | Power not stated | 5 | 0 | 0.25 | 0.25 |
| 20 nm) | (CW single-mode dye | | | | |
| Ref: Reiter, D. E., Axt, V. M. & | ring laser) | | | | |
| Kuhn, T. Optical signals of spin | | | | | |
| switching using the optical Stark | | | | | |
| effect in a Mn-doped quantum dot. | | | | | |
| Physical Review B 87, 115430 | | | | | |
| (2013). | | | | | |
| 9.6 nm GaAs/9.8 nm | 8 MW/cm² | 70 | 18 | 0.1 | 1.9 |
| Al_{0.27}Ga_{0.73}As MQW | (6-ps 6.7-MHz mode- | | | | |
| Ref: Von Lehmen, A., Chemla, D. | locked cavity dumped | | | | |
| S., Heritage, J. P. & Zucker, J. E. | dye laser) | | | | |
| Optical Stark effect on excitons in | | | | | |
| GaAs quantum wells. Opt. Lett. 11, | | | | | |
| 609-611, | | | | | |
| doi: 10.1364/OL.11.000609 (1986). | | | | | |
| 10 nm GaAs/10 nm A1GaAs | ~10 GW/cm² | 15 | 29 | ~1.4* | 9.1 |
| MQW | (150-fs colliding-pulse | | | | |
| Ref: Mysyrowicz, A. et al. “Dressed | mode-locked laser.) | | | | |
| Excitons” in a Multiple-Quantum- | | | | | |
| Well Structure: Evidence for an | | | | | |
| Optical Stark Effect with | | | | | |
| Femtosecond Response Time. | | | | | |
| Physical Review Letters 56, 2748- | | | | | |
| 2751 (1986). | | | | | |
| 10 nm GaAs/2.5 nm A1GaAs | ~10 GW/cm² | 15 | 19 | ~3.5^{#} | 12 |
| MQW | (150-fs colliding-pulse | | | | |
| Ref: Mysyrowicz, A. et al. “Dressed | mode-locked laser.) | | | | |
| Excitons” in a Multiple-Quantum- | | | | | |
| Well Structure: Evidence for an | | | | | |
| Optical Stark Effect with | | | | | |
| Femtosecond Response Time. | | | | | |
| Physical Review Letters 56, 2748- | | | | | |
| 2751 (1986). | | | | | |
| Single InAs QD (50 nm) in | 60 μW | 14 | 0.43 | 0.083 | 0.28 |
| GaAs photonic crystal | (CW 300-kHz-FWHM | | | | |
| Ref: Bose, R., Sridharan, D., | λ-tunable laser diode) | | | | |
| Solomon, G. S. & Waks, E. Large | | | | | |
| optical Stark shifts in | | | | | |
| semiconductor quantum dots | | | | | |
| coupled to photonic crystal cavities. | | | | | |
| Applied Physics Letters 98, 121109, | | | | | |
| doi: 10.1063/1.3571446 (2011). | | | | | |
| Single Interface QD (50 nm) in | 0.2 μW | 12 | 3 | ~0.47 | 1.75 |
| GaAs/AlAs superlattice | (2-ps 0.8-meV-FWHM | | | | |
| Ref: Unold, T., Mueller, K., Lienau, | Ti:S oscillator + fiber) | | | | |
| C., Elsaesser, T. & Wieck, A. D. | | | | | |
| Optical Stark Effect in a Quantum | | | | | |
| Dot: Ultrafast Control of Single | | | | | |
| Exciton Polarizations. Physical | | | | | |
| Review Letters 92, 157401 (2004). | | | | | |

*Estimated energy shift from FIG. 1 by Mysyrowicz et al.
^{#}Estimated energy shift from FIG. 2 by Mysyrowicz et al.
^{†}The value is estimated from Eq. (38), if not directly mentioned.

Compilation of various OSE and Rabi splitting in semiconductor nanostructures reported in the literatures. The information of laser system and intensity/power used to obtain such splitting is also included. Abbreviation of MQW, QD and CW refer to multiple quantum well, quantum dot and continuous wave, respectively.

### Estimation of the Equivalent B-Field for Zeeman Splitting of Energy Levels

The energy level E for a system in a magnetic field B is given by:

E=E₀±½g_{J}μ_{B}m_{J}B+c₀B² (43)

Here, E₀ is the energy level in the absence of a B-field, g_{J} is the effective g-factor, m_{J} is the projection of total angular momentum quantum number in z direction (i.e. B-field direction), μ_{B}=57.88 μeV/T is the Bohr magneton and c₀ is the diamagnetic coefficient. The + and − signs refer to states with the magnetic moment anti-parallel and parallel to the B-field, respectively. For a system with m_{J}=½, the splitting of the spin-state gives rise to:

ΔE=E₊−E₋=g_{J}μ_{B}B (44)

where E₊ and E₋ correspond to the absorption of σ⁺ and σ⁻, respectively.

However, there are no reports in literature on the measurement of spin-state splitting by B-field for PEPI (i.e. Zeeman Effect) nor its g-factor. Considering that the organic component only gives a weak contribution, the inventors proceed to estimate the equivalent B-field for the OSE splitting in PEPI using the g values measured for a similar perovskite that has a different organic component (C₁₀H₂₁NH₃)₂PbI₄. There is a range of values reported for the g-factor of (C₁₀H₂₁NH₃)₂PbI₄. Xu, C.-q. et al. (Magneto-optical effects of excitons in (C₁₀H₂₁NH₃)₂PbI₄ under high magnetic fields up to 40 T. Solid State Communications 79, 249-253, doi:10.1016/0038-1098(91)90644-B (1991)) reported g-factors of 0.77-1.08. Using these values, the inventors obtained an equivalent B-field of ˜71 T to ˜99 T (or ˜99 T to 140 T) for the 4.5 meV (or 6.3 meV) energy splitting. On the other hand, Hirasawa et al. (Magnetoreflection of the lowest exciton in a layered perovskite-type compound (C₁₀H₂₁NH₃)₂PbI₄. Solid State Communications 86, 479-483, doi:10.1016/0038-1098(93)90092-2 (1993)) reported a value of 1.42, which would yield an estimated equivalent B-field of ˜54 T (or ˜76 T) for the 4.5 meV (or 6.3 meV) splitting. Hence, the inventors conservatively estimate that that the OSE-induced spin-state splitting in PEPI (or fluorinated PEPI) is equivalent with a Zeeman splitting with B-field of >50 Tesla (or >70 T).

### Estimation of the Transition Dipole Moment (TDM)

From the present results, the inventors can also estimate the exciton transition dipole moment (TDM) of PEPI. The electric field F due to presently used pump pulse of 1.66 mJ/cm² (at 2.16 eV) can be estimated using the relation with the peak intensity I:

$$I = \frac{fluence}{duration} = \frac{1}{2} n {ò}_{0} {cF}^{2}$$

where n≈2.1±0.1) is the refractive index of PEPI film. From this relation, the inventors obtain F=143±4 MV/m, with pulse duration of 290 fs (FIG. 21B). From semi-classical quantum theory, the Rabi frequency of a system is related to the electric field F of the EM radiation through:

ÅΩ_{R}=|p₁₂|F∝\sqrt{Intensity} (46)

Given Ω_{R}=47±2 meV, the transition dipole moment is determined to be |p₁₂|=(5.26±0.20)×10⁻²⁹ Cm=15.8±0.6 Debye.

### Estimation of Ω_{R} and Oscillator Strength in Various Organic-Inorganic Halide Perovskite Systems

FIG. 22A-D shows comparison of three halide perovskite system with varying dielectric contrast between the barrier and the well layers, from the lowest to highest: (C₆H₅C₂H₄NH₃)₂PbBr₄ (named as PEPB), PEPI and (C₆H₄FC₂H₄NH₃)₂PbI₄ (named as FPEPI—see FIG. 22A). FIG. 22B and FIG. 22C show a linear and square-root dependence of observed Stark shift and Rabi splitting to the pump fluence, which is in accordance to Eq. (38) and Eq. (46), respectively. Higher Rabi splitting is achieved by halide perovskite system with larger dielectric contrast, which implies it as the determining parameter for light-matter coupling strength in this material system. At fluence of 1.66 mJ/cm2, the inventors achieve ΔE of 1.2±0.1 meV (at Δ=0.46 eV), 4.5±0.2 meV (at Δ=0.23 eV) and 6.3±0.3 meV (at Δ=0.23 eV) for PEPB, PEPI and FPEPI, respectively. These values corresponds to respective Rabi splitting Ω_{R} of 33±3 meV, 47±2 meV and 55±2 meV, respectively.

Meanwhile, it is known that the oscillator strength ƒ of a transition is proportional to the integration of the absorption coefficient over the spectrum—Eq. (47).

$$f ∝ {{\int }_{0}}^{∞} α ( ω ) d ω \qquad ( 47 )$$

The oscillator strengths of these three materials are therefore estimated by integrating the area of Lorenztian function fitted to the free exciton peak—FIG. S7c. Given the oscillator strength of PEPI to be ˜0.5, the oscillator strength for two other materials are scaled accordingly. The inventors estimate the oscillator strength of PEPB to be ˜0.99 (indicated by much stronger absorption), while the oscillator strength of FPEPI to be ˜0.54 (similar to PEPI). Surprisingly PEPB, while having a lowest dielectric contrast and Rabi splitting among, it possesses the highest oscillator strength.

### Estimation of the Radiative Lifetime

Using the obtained transition dipole moment (TDM), the inventors estimate the radiative lifetime (spontaneous emission) of the system. The spontaneous emission rate or Einstein coefficient A, is related to the transition dipole moment through:

$${τ}_{R} = {A}^{- 1} = {( \frac{{n}^{3} {ω}_{0}^{3} {\vert {p}_{12} \vert}^{2}}{3 {ò}_{0} π ℏ {c}^{3}} )}^{- 1} \qquad ( 48 )$$

Using the obtained |p₁₂|, the inventors estimate the radiative lifetime to be 190±10 ps. This value is consistent with the present measurement of the time-resolved photoluminescence (PL) lifetime of 210±10 ps, as shown in FIG. 23. This further validates the estimation of |p₁₂|.

### Estimation of the Exciton Reduced Mass

The relation between the transition dipole moment (TDM), oscillator strength ƒ and effective mass m* is given by:

$$f = \frac{2 {m}^{*} {ω}_{12} {\vert {p}_{12} \vert}^{2}}{3 {e}^{2} ℏ} \qquad ( 49 )$$

Here, ω₂ is the transition frequency between states |1 [symbol] and |2 [symbol] . For PEPI, the oscillator strength has been reported to be ƒ=˜0.5. Hence, the electron effective mass can be calculated to be m*=(0.22±0.01)m₀, where m₀=9.1×10⁻³¹ kg is the rest mass of free electron. Assuming the effective mass of electron and hole mₑ*=mₕ*, which is common assumption for layered perovskite system, the exciton reduced mass is therefore given by:

$${μ}_{x} = {( \frac{1}{{m}_{e}^{*}} + \frac{1}{{m}_{h}^{*}} )}^{- 1} = ( 0.11 \pm 0.01 ) {m}_{0} \qquad ( 50 )$$

This result is consistent with the report from Hong et al. (Dielectric confinement effect on excitons in PbI-based layered semiconductors. Physical Review B 45, 6961-6964 (1992)), which is estimated by using different experimental techniques.

### Oscillatory Signal in PEPI

As shown in FIG. 14D, the kinetics for pump energy of 2.16 eV, which is below exciton absorption peak at 2.39 eV, shows a strong OSE signal and a weak oscillatory PB signal. To determine the origin of the oscillatory signal, the inventors performed pump-probe measurement with above bandgap pump excitation of 3.10 eV (i.e., high enough to allow direct excitation of the excitons)—FIG. 24. The data shows a similar oscillatory signal of ˜1 THz frequency, which confirms the inventors' deduction that the oscillations originate from the excitons. Hirasawa et al. (supra) observed a strong Raman signal from optical phonons at 6.3 meV (˜1.5 THz) for a similar layered perovskite (C₁₀H₂₁NH₃)₂PbI₄. This oscillatory signal could be from exciton-phonon interactions. Further experiments are required for its verification.

By “comprising” it is meant including, but not limited to, whatever follows the word “comprising”. Thus, use of the term “comprising” indicates that the listed elements are required or mandatory, but that other elements are optional and may or may not be present.

By “consisting of” is meant including, and limited to, whatever follows the phrase “consisting of”. Thus, the phrase “consisting of” indicates that the listed elements are required or mandatory, and that no other elements may be present.

The inventions illustratively described herein may suitably be practiced in the absence of any element or elements, limitation or limitations, not specifically disclosed herein. Thus, for example, the terms “comprising”, “including”, “containing”, etc. shall be read expansively and without limitation. Additionally, the terms and expressions employed herein have been used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the inventions embodied therein herein disclosed may be resorted to by those skilled in the art, and that such modifications and variations are considered to be within the scope of this invention.

By “about” in relation to a given numerical value, such as for temperature and period of time, it is meant to include numerical values within 10% of the specified value.

The invention has been described broadly and generically herein. Each of the narrower species and sub-generic groupings falling within the generic disclosure also form part of the invention. This includes the generic description of the invention with a proviso or negative limitation removing any subject matter from the genus, regardless of whether or not the excised material is specifically recited herein.

Other embodiments are within the following claims and non-limiting examples. In addition, where features or aspects of the invention are described in terms of Markush groups, those skilled in the art will recognize that the invention is also thereby described in terms of any individual member or subgroup of members of the Markush group.

### REFERENCES

1 Le Gall, C., Brunetti, A., Boukari, H. & Besombes, L. Optical Stark Effect and Dressed Exciton States in a Mn-Doped CdTe Quantum Dot. Physical Review Letters 107, 057401 (2011).
2 Reiter, D. E., Axt, V. M. & Kuhn, T. Optical signals of spin switching using the optical Stark effect in a Mn-doped quantum dot. Physical Review B 87, 115430 (2013).
3 \check{Z}utić, I., Fabian, J. & Das Sarma, S. Spintronics: Fundamentals and Applications. Reviews of Modern Physics 76, 323-410 (2004).
4 Amo A et al. Exciton-polariton spin switches. Nat Photon 4, 361-366, doi:10.1038/nphoton.2010.79 (2010).
5 Fröhlich, D., Wille, R., Schlapp, W. & Weimann, G. Optical quantum-confined Stark effect in GaAs quantum wells. Physical Review Letters 59, 1748-1751 (1987).
6 Von Lehmen, A., Chemla, D. S., Heritage, J. P. & Zucker, J. E. Optical Stark effect on excitons in GaAs quantum wells. Opt. Lett. 11, 609-611, doi:10.1364/OL.11.000609 (1986).
7 Bose, R., Sridharan, D., Solomon, G. S. & Waks, E. Large optical Stark shifts in semiconductor quantum dots coupled to photonic crystal cavities. Applied Physics Letters 98, 121109, doi:10.1063/1.3571446 (2011).
8 Unold, T., Mueller, K., Lienau, C., Elsaesser, T. & Wieck, A. D. Optical Stark Effect in a Quantum Dot: Ultrafast Control of Single Exciton Polarizations. Physical Review Letters 92, 157401 (2004).
9 Yang, W. S. et al. High-performance photovoltaic perovskite layers fabricated through intramolecular exchange. Science 348, 1234-1237, doi:10.1126/science.aaa9272 (2015).
10 Giovanni, D. et al. Highly Spin-Polarized Carrier Dynamics and Ultralarge Photoinduced Magnetization in CH₃NH₃PbI₃ Perovskite Thin Films. Nano Letters 15, 1553-1558, doi:10.1021/n15039314 (2015).
11 Miyata, A. et al. Direct measurement of the exciton binding energy and effective masses for charge carriers in organic-inorganic tri-halide perovskites. Nat Phys 11, 582-587, doi:10.1038/nphys3357 (2015).
12 Zhang, C. et al. Magnetic field effects in hybrid perovskite devices. Nat Phys 11, 427-434, doi:10.1038/nphys3277 (2015).
13 Hsiao, Y.-C., Wu, T., Li, M. & Hu, B. Magneto-Optical Studies on Spin-Dependent Charge Recombination and Dissociation in Perovskite Solar Cells. Advanced Materials 27, 2899-2906, doi:10.1002/adma.201405946 (2015).
14 Mitzi, D. B., Chondroudis, K. & Kagan, C. R. Organic-inorganic electronics. IBM J. Res. Dev. 45, 29-45, doi:10.1147/rd.451.0029 (2001).
15 Kagan, C. R., Mitzi, D. B. & Dimitrakopoulos, C. D. Organic-Inorganic Hybrid Materials as Semiconducting Channels in Thin-Film Field-Effect Transistors. Science 286, 945-947, doi:10.1126/science.286.5441.945 (1999).
16 Mitzi, D. B., Dimitrakopoulos, C. D. & Kosbar, L. L. Structurally Tailored Organic-Inorganic Perovskites: Optical Properties and Solution-Processed Channel Materials for Thin-Film Transistors. Chemistry of Materials 13, 3728-3740, doi:10.1021/cm010105g (2001).
17 Mitzi, D. B. et al. Hybrid Field-Effect Transistor Based on a Low-Temperature Melt-Processed Channel Layer. Advanced Materials 14, 1772-1776, doi:10.1002/1521-4095(20021203)14:23<1772::AID-ADMA 1772>3.0.CO;2-Y (2002).
18 Matsushima, T., Fujita, K. & Tsutsui, T. Electroluminescence enhancement in dry-processed organic-inorganic layered perovskite films. Japanese journal of applied physics 44, 1457 (2005).
19 Kenichiro, T. et al. Electronic and Excitonic Structures of Inorganic-Organic Perovskite-Type Quantum-Well Crystal (C₄H₉NH₃)₂PbBr₄. Japanese Journal of Applied Physics 44, 5923 (2005).
20 Even, J., Pedesseau, L., Dupertuis, M. A., Jancu, J. M. & Katan, C. Electronic model for self-assembled hybrid organic/perovskite semiconductors: Reverse band edge electronic states ordering and spin-orbit coupling. Physical Review B 86, 205301 (2012).
21 Ishihara, T., Takahashi, J. & Goto, T. Optical properties due to electronic transitions in two-dimensional semiconductors (CₙH₂ₙ₊₁NH₃)₂PbI₄. Physical Review B 42, 11099-11107 (1990).
22 Brehier, A., Parashkov, R., Lauret, J. S. & Deleporte, E. Strong exciton-photon coupling in a microcavity containing layered perovskite semiconductors. Applied Physics Letters 89, 171110, doi:10.1063/1.2369533 (2006).
23 Lanty, G., Bréhier, A., Parashkov, R., Lauret, J. S. & Deleporte, E. Strong exciton-photon coupling at room temperature in microcavities containing two-dimensional layered perovskite compounds. New Journal of Physics 10, 065007 (2008).
24 Autler, S. H. & Townes, C. H. Stark Effect in Rapidly Varying Fields. Physical Review 100, 703-722 (1955).
25 Hong, X., Ishihara, T. & Nurmikko, A. V. Dielectric confinement effect on excitons in PbI₄-based layered semiconductors. Physical Review B 45, 6961-6964 (1992).
26 Mysyrowicz, A. et al. “Dressed Excitons” in a Multiple-Quantum-Well Structure:

Evidence for an Optical Stark Effect with Femtosecond Response Time. Physical Review Letters 56, 2748-2751 (1986).
27 Sie, E. J. et al. Valley-selective optical Stark effect in monolayer WS₂. Nat Mater 14, 290-294, doi:10.1038/nmat4156 (2015).
28 Withers, F., Bointon, T. H., Hudson, D. C., Craciun, M. F. & Russo, S. Electron transport of WS2 transistors in a hexagonal boron nitride dielectric environment. Scientific Reports 4, 4967, doi:10.1038/srep04967 (2014).
29 Even, J.; Pedesseau, L.; Katan, C., Analysis of Multivalley and Multibandgap Absorption and Enhancement of Free Carriers Related to Exciton Screening in Hybrid Perovskites. The Journal of Physical Chemistry C 2014, 118 (22), 11566-11572.
30 Tanaka, K.; Takahashi, T.; Ban, T.; Kondo, T.; Uchida, K.; Miura, N., Comparative Study on the Excitons in Lead-Halide-Based Perovskite-Type Crystals CH3NH3PbBr3 CH3NH3PbI3. Solid State Communications 2003, 127 (9-10), 619-623.
31 Umebayashi, T.; Asai, K.; Kondo, T.; Nakao, A., Electronic structures of lead iodide based low-dimensional crystals. Physical Review B 2003, 67 (15), 155405.
32 Kim, M.; Im, J.; Freeman, A. J.; Ihm, J.; Jin, H., Switchable S=½ and J=½ Rashba bands in ferroelectric halide perovskites. Proceedings of the National Academy of Sciences 2014, 111 (19), 6900-6904.
33 Kimball, D. F. J.; Alexandrov, E. B.; Budker, D., General Principles and Characteristics of Optical Magnetometers In Optical Magnetometry, Dmitry Budker, D. F. J. K., Ed. Cambridge University Press: Cambridge, 2013; pp 1-24.
34 Holub, M.; Bhattacharya, P., Spin-Polarized Light-Emitting Diodes and Lasers. Journal of Physics D: Applied Physics 2007, 40 (11), R179.
35 \check{Z}utić, I.; Fabian, J.; Das Sarma, S., Spintronics: Fundamentals and Applications. Reviews of Modern Physics 2004, 76 (2), 323-410.
36 Crooker, S. A.; Awschalom, D. D.; Samarth, N., Time-resolved Faraday rotation spectroscopy of spin dynamics in digital magnetic heterostructures. Selected Topics in Quantum Electronics, IEEE Journal of 1995, 1 (4), 1082-1092.
37 Wu, M. W.; Jiang, J. H.; Weng, M. Q., Spin dynamics in semiconductors. Physics Reports 2010, 493 (2-4), 61-236.
38 Uemoto, M. & Ajiki, H. Large and well-defined Rabi splitting in a semiconductor nanogap cavity. Opt. Express 22, 22470-22478, doi:10.1364/OE.22.022470 (2014).
39 Khitrova, G., Gibbs, H. M., Kira, M., Koch, S. W. & Scherer, A. Vacuum Rabi splitting in semiconductors. Nat Phys 2, 81-90 (2006).
40 Lanty, G., Bréhier, A., Parashkov, R., Lauret, J. S. & Deleporte, E. Strong exciton-photon coupling at room temperature in microcavities containing two-dimensional layered perovskite compounds. New Journal of Physics 10, 065007 (2008).
41 Reiter, D. E., Axt, V. M. & Kuhn, T. Optical signals of spin switching using the optical Stark effect in a Mn-doped quantum dot. Physical Review B 87, 115430 (2013).
42 Von Lehmen, A., Chemla, D. S., Heritage, J. P. & Zucker, J. E. Optical Stark effect on excitons in GaAs quantum wells. Opt. Lett. 11, 609-611, doi:10.1364/OL.11.000609 (1986).
43 Mysyrowicz, A. et al. “Dressed Excitons” in a Multiple-Quantum-Well Structure:

Evidence for an Optical Stark Effect with Femtosecond Response Time. Physical Review Letters 56, 2748-2751 (1986).
44 Bose, R., Sridharan, D., Solomon, G. S. & Waks, E. Large optical Stark shifts in semiconductor quantum dots coupled to photonic crystal cavities. Applied Physics Letters 98, 121109, doi:10.1063/1.3571446 (2011).
45 Unold, T., Mueller, K., Lienau, C., Elsaesser, T. & Wieck, A. D. Optical Stark Effect in a Quantum Dot: Ultrafast Control of Single Exciton Polarizations. Physical Review Letters 92, 157401 (2004).
46 Ishihara, T., Takahashi, J. & Goto, T. Optical properties due to electronic transitions in two-dimensional semiconductors (CₙH₂ₙ₊₁NH₃)₂PbI₄. Physical Review B 42, 11099-11107 (1990).
47 Xu, C.-q. et al. Magneto-optical effects of excitons in (C₁₀H₂₁NH₃)₂PbI₄ under high magnetic fields up to 40 T. Solid State Communications 79, 249-253, doi:10.1016/0038-1098(91)90644-B (1991).
48 Hirasawa, M. et al. Magnetoreflection of the lowest exciton in a layered perovskite-type compound (C₁₀H₂₁NH₃)₂PbI₄. Solid State Communications 86, 479-483, doi:10.1016/0038-1098(93)90092-2 (1993).
49 Zhang, S. et al. Preparations and Characterizations of Luminescent Two Dimensional Organic-inorganic Perovskite Semiconductors. Materials 3, 3385 (2010).
50 Niu, W., Eiden, A., Vijaya Prakash, G. & Baumberg, J. J. Exfoliation of self-assembled 2D organic-inorganic perovskite semiconductors. Applied Physics Letters 104, 171111, doi:10.1063/1.4874846 (2014).
51 Hilborn, R. C. Einstein coefficients, cross sections, f values, dipole moments, and all that. American Journal of Physics 50, 982-986, doi:10.1119/1.12937 (1982).
52 Hong, X., Ishihara, T. & Nurmikko, A. V. Dielectric confinement effect on excitons in PbI₄-based layered semiconductors. Physical Review B 45, 6961-6964 (1992).
53 Kenichiro, T. & Takashi, K. Bandgap and exciton binding energies in lead-iodide-based natural quantum-well crystals. Science and Technology of Advanced Materials 4, 599 (2003).

1. A spintronic device comprising a spintronic material, wherein the spintronic material comprises a halide perovskite compound.

2. The spintronic device according to claim 1, wherein the spintronic material comprises a two-dimensional/layered or three-dimensional halide perovskite compound.

3. The spintronic device according to claim 1, wherein the spintronic material comprises a solution processed halide perovskite compound.

4. The spintronic device according to claim 3, wherein the solution processed halide perovskite compound is formed by depositing onto a substrate a precursor solution comprising RX and MX₂ dissolved in a solvent, wherein R comprises an organic group or inorganic cation, M comprises a metal cation and X comprises I, Cl, Br, F, or a mixture thereof, followed by heating the deposited precursor solution.

5. The spintronic device according to claim 4, where R comprises an organic or inorganic cation.

6. The spintronic device according to claim 5, wherein R is selected from the group consisting of ammonium ion, hydroxyl-ammonium ion, hydrazinium ion, azeditinium ion, formamidinium ion, imidazolium ion, dimethylammonium ion, guanidinium ion, alkyl-ammonium ion, arylalkyl-ammonium ion, Cs⁺, K⁺, Rb⁺, and a mixture thereof.

7. The spintronic device according to claim 4, wherein the solution processed halide perovskite compound comprises one or more metal cations selected from cationic 2⁺ group.

8. The spintronic device according to claim 4, wherein the solution processed halide perovskite comprises one or more halide anions selected from a group consisting of F⁻, Cl⁻, Br⁻ and I⁻.

9. The spintronic device according to claim 4, wherein the precursor solution is deposited by drop-casting, spin-coating, or dip-coating.

10. The spintronic device according to claim 1, wherein the spintronic device is a quantum computing device, spin-switch, spin-polarized laser and light emitting device, spin-transistor, amplitude modulator in optical isolator or optical circulator for optical communication, or sensing element for remote sensing of magnetic field.

11. The spintronic device according to claim 1, wherein the halide perovskite compound comprises a general formula RMX₃, wherein R comprises a mono-positive organic group or inorganic cation, M comprises a divalent metal cation, and X comprises I, Cl, Br, F, or a mixture thereof.

12. The spintronic device according to claim 1, wherein the halide perovskite compound comprises a general formula R₂MX₆, where R comprises a mono-positive organic group or inorganic cation, M comprises a tetravalent metal cation, and X comprises I, Cl, Br, F, or a mixture thereof.

13. The spintronic device according to claim 1, wherein the halide perovskite compound comprises a general formula R₂MX₄, where R comprises a mono-positive organic group or inorganic cation, M comprises a divalent metal cation, and X comprises I, Cl, Br, F, or a mixture thereof.

14. The spintronic device according to claim 1, wherein the halide perovskite compound comprises a general formula RMX₄, where R comprises a bi-positive organic group or inorganic cation, M comprises a divalent metal cation and X comprises I, Cl, Br, F, or a mixture thereof.

15. A method for forming a halide perovskite compound, the method comprising:
dissolving RX and MX₂ in a solvent to form a precursor solution, wherein R comprises an organic group or an inorganic cation, M comprises a divalent metal and X comprises I, Cl, Br, F, or a mixture thereof,
depositing the precursor solution onto a substrate; and
heating the deposited precursor solution to form a film of the organic lead halide perovskite compound.

16. The method according to claim 15, wherein R is selected from a group consisting of ammonium ion, hydroxyl-ammonium ion, hydrazinium ion, azeditinium ion,
formamidinium ion, imidazolium ion, dimethylammonium ion, guanidinium ion, alkyl-ammonium ion, arylalkyl-ammonium ion, Cs⁺, K⁺, Rb⁺, and a mixture thereof.

17. The method according to claim 15, wherein the solvent is a polar solvent.

18. The method according to claim 17, wherein the polar solvent is selected from the group consisting of N,N-dimethyl formamide, dimethyl sulfoxide (DMSO) or gamma butyrylactone.

19. The method according to claim 15, wherein depositing comprises drop-casting, spin-coating, or dip-coating.
